(19) United States
(12) Patent Application Publication
(10) Pub. No.: US 2026/0162694 A1
(43) Pub. Date: Jun. 11, 2026

(54) MEMORY DEVICE

(71) Applicant: Kioxia Corporation, Tokyo (JP)

(72) Inventors: Ryo Fukuoka, Yokkaichi Mie (JP); Kouji Matsuo, Ama Aichi (JP); Yoshiro Shimojo, Nagoya Aichi (JP)

(73) Assignee: Kioxia Corporation, Tokyo (JP)

(21) Appl. No.: 19/323,611

(22) Filed: Sep. 9, 2025

(30) Foreign Application Priority Data
Dec. 9, 2024 (JP) 2024-214720

(51) Int. Cl. G11C 5/06; G11C 16/04; H10B 41/10; H10B 41/27; H10B 41/35; H10B 43/10; H10B 43/27; H10B 43/35

(52) U.S. Cl. CPC G11C 5/063; G11C 16/0483; H10B 41/10; H10B 41/27; H10B 41/35; H10B 43/10; H10B 43/27; H10B 43/35

(57) ABSTRACT

According to one embodiment, a memory device includes: first and second conductive pillars each extending in a first direction and arranged in a second direction; first and second semiconductor layers each extending in the second direction at a first position in the first direction and sandwiching the first and second conductive pillars in a third direction; a first insulator film between the first and second semiconductor layers and between the first and second conductive pillars at the first position and having a first portion along a circle centered on the first conductive pillar; a first charge storage film between the first conductive pillar and the first semiconductor layer at the first position; and a second charge storage film between the first conductive pillar and the second semiconductor layer at the first position and separated from the first charge storage film.

### CROSS-REFERENCE TO RELATED APPLICATIONS

This application is based upon and claims the benefit of priority from Japanese Patent Application No. 2024-214720, filed Dec. 9, 2024, the entire contents of which are incorporated herein by reference.

### FIELD

Embodiments described herein relate generally to a memory device.

### BACKGROUND

A NAND flash memory is known as a memory device capable of storing data in a nonvolatile manner. In such a memory device such as a NAND flash memory, a three-dimensional memory structure is adopted for enhanced integration and increased capacity.

### BRIEF DESCRIPTION OF DRAWINGS

FIG. 1 is a block diagram illustrating an example of the configuration of a memory system including a memory device according to a first embodiment.

FIG. 2 is a circuit diagram illustrating an example of the circuit configuration of a memory cell array included in the memory device according to the first embodiment.

FIG. 3 is a plan view illustrating an example of the planar layout of the memory cell array according to the first embodiment.

FIG. 4 is a cross-sectional view taken along line IV-IV of FIG. 3, illustrating an example of the cross-sectional structure of the memory cell array according to the first embodiment.

FIG. 5 is a plan view illustrating an example of the planar layout in a process of manufacturing the memory device according to the first embodiment.

FIG. 6 is a cross-sectional view illustrating an example of the cross-sectional structure in a process of manufacturing the memory device according to the first embodiment.

FIG. 7 is a plan view illustrating an example of the planar layout in a process of manufacturing the memory device according to the first embodiment.

FIG. 8 is a cross-sectional view illustrating an example of the cross-sectional structure in a process of manufacturing the memory device according to the first embodiment.

FIG. 9 is a plan view illustrating an example of the planar layout in a process of manufacturing the memory device according to the first embodiment.

FIG. 10 is a cross-sectional view illustrating an example of the cross-sectional structure in a process of manufacturing the memory device according to the first embodiment.

FIG. 11 is a plan view illustrating an example of the planar layout in a process of manufacturing the memory device according to the first embodiment.

FIG. 12 is a cross-sectional view illustrating an example of the cross-sectional structure in a process of manufacturing the memory device according to the first embodiment.

FIG. 13 is a plan view illustrating an example of the planar layout in a process of manufacturing the memory device according to the first embodiment.

FIG. 14 is a cross-sectional view illustrating an example of the cross-sectional structure in a process of manufacturing the memory device according to the first embodiment.

FIG. 15 is a plan view illustrating an example of the planar layout in a process of manufacturing the memory device according to the first embodiment.

FIG. 16 is a cross-sectional view illustrating an example of the cross-sectional structure in a process of manufacturing the memory device according to the first embodiment.

FIG. 17 is a plan view illustrating an example of the planar layout in a process of manufacturing the memory device according to the first embodiment.

FIG. 18 is a cross-sectional view illustrating an example of the cross-sectional structure in a process of manufacturing the memory device according to the first embodiment.

FIG. 19 is a plan view illustrating an example of the planar layout in a process of manufacturing the memory device according to the first embodiment.

FIG. 20 is a cross-sectional view illustrating an example of the cross-sectional structure in a process of manufacturing the memory device according to the first embodiment.

FIG. 21 is a plan view illustrating an example of the planar layout in a process of manufacturing the memory device according to the first embodiment.

FIG. 22 is a cross-sectional view illustrating an example of the cross-sectional structure in a process of manufacturing the memory device according to the first embodiment.

FIG. 23 is a plan view illustrating an example of the planar layout in a process of manufacturing the memory device according to the first embodiment.

FIG. 24 is a cross-sectional view illustrating an example of the cross-sectional structure in a process of manufacturing the memory device according to the first embodiment.

FIG. 25 is a plan view illustrating an example of the planar layout in a process of manufacturing the memory device according to the first embodiment.

FIG. 26 is a cross-sectional view illustrating an example of the cross-sectional structure in a process of manufacturing the memory device according to the first embodiment.

FIG. 27 is a circuit diagram illustrating an example of the circuit configuration of a memory cell array included in a memory device according to a modification of the first embodiment.

FIG. 28 is a cross-sectional view illustrating an example of the cross-sectional structure of the memory cell array according to the modification of the first embodiment.

FIG. 29 is a plan view illustrating an example of the planar layout of a memory cell array according to a second embodiment.

FIG. 30 is a cross-sectional view taken along line XXX-XXX of FIG. 29, illustrating an example of the cross-sectional structure of the memory cell array according to the second embodiment.

FIG. 31 is a plan view illustrating an example of the planar layout in a process of manufacturing a memory device according to the second embodiment.

FIG. 32 is a cross-sectional view illustrating an example of the cross-sectional structure in a process of manufacturing the memory device according to the second embodiment.

FIG. 33 is a plan view illustrating an example of the planar layout in a process of manufacturing the memory device according to the second embodiment.

FIG. 34 is a cross-sectional view illustrating an example of the cross-sectional structure in a process of manufacturing the memory device according to the second embodiment.

FIG. 35 is a plan view illustrating an example of the planar layout in a process of manufacturing the memory device according to the second embodiment.

FIG. 36 is a cross-sectional view illustrating an example of the cross-sectional structure in a process of manufacturing the memory device according to the second embodiment.

FIG. 37 is a plan view illustrating an example of the planar layout in a process of manufacturing the memory device according to the second embodiment.

FIG. 38 is a cross-sectional view illustrating an example of the cross-sectional structure in a process of manufacturing the memory device according to the second embodiment.

FIG. 39 is a plan view illustrating an example of the planar layout in a process of manufacturing the memory device according to the second embodiment.

FIG. 40 is a cross-sectional view illustrating an example of the cross-sectional structure in a process of manufacturing the memory device according to the second embodiment.

FIG. 41 is a plan view illustrating an example of the planar layout in a process of manufacturing the memory device according to the second embodiment.

FIG. 42 is a cross-sectional view illustrating an example of the cross-sectional structure in a process of manufacturing the memory device according to the second embodiment.

FIG. 43 is a plan view illustrating an example of the planar layout in a process of manufacturing the memory device according to the second embodiment.

FIG. 44 is a cross-sectional view illustrating an example of the cross-sectional structure in a process of manufacturing the memory device according to the second embodiment.

FIG. 45 is a plan view illustrating an example of the planar layout in a process of manufacturing the memory device according to the second embodiment.

FIG. 46 is a cross-sectional view illustrating an example of the cross-sectional structure in a process of manufacturing the memory device according to the second embodiment.

FIG. 47 is a plan view illustrating an example of the planar layout in a process of manufacturing the memory device according to the second embodiment.

FIG. 48 is a cross-sectional view illustrating an example of the cross-sectional structure in a process of manufacturing the memory device according to the second embodiment.

FIG. 49 is a plan view illustrating an example of the planar layout of a memory cell array according to a third embodiment.

FIG. 50 is a cross-sectional view taken along line L-L of FIG. 49, illustrating an example of the cross-sectional structure of the memory cell array according to the third embodiment.

FIG. 51 is a plan view illustrating an example of the planar layout in a process of manufacturing a memory device according to the third embodiment.

FIG. 52 is a cross-sectional view illustrating an example of the cross-sectional structure in a process of manufacturing the memory device according to the third embodiment.

FIG. 53 is a plan view illustrating an example of the planar layout in a process of manufacturing the memory device according to the third embodiment.

FIG. 54 is a cross-sectional view illustrating an example of the cross-sectional structure in a process of manufacturing the memory device according to the third embodiment.

FIG. 55 is a plan view illustrating an example of the planar layout in a process of manufacturing the memory device according to the third embodiment.

FIG. 56 is a cross-sectional view illustrating an example of the cross-sectional structure in a process of manufacturing the memory device according to the third embodiment.

FIG. 57 is a plan view illustrating an example of the planar layout in a process of manufacturing the memory device according to the third embodiment.

FIG. 58 is a cross-sectional view illustrating an example of the cross-sectional structure in a process of manufacturing the memory device according to the third embodiment.

FIG. 59 is a plan view illustrating an example of the planar layout in a process of manufacturing the memory device according to the third embodiment.

FIG. 60 is a cross-sectional view illustrating an example of the cross-sectional structure in a process of manufacturing the memory device according to the third embodiment.

FIG. 61 is a plan view illustrating an example of the planar layout in a process of manufacturing the memory device according to the third embodiment.

FIG. 62 is a cross-sectional view illustrating an example of the cross-sectional structure in a process of manufacturing the memory device according to the third embodiment.

FIG. 63 is a plan view illustrating an example of the planar layout in a process of manufacturing the memory device according to the third embodiment.

FIG. 64 is a cross-sectional view illustrating an example of the cross-sectional structure in a process of manufacturing the memory device according to the third embodiment.

FIG. 65 is a plan view illustrating an example of the planar layout in a process of manufacturing the memory device according to the third embodiment.

FIG. 66 is a cross-sectional view illustrating an example of the cross-sectional structure in a process of manufacturing the memory device according to the third embodiment.

FIG. 67 is a plan view illustrating an example of the planar layout in a process of manufacturing the memory device according to the third embodiment.

FIG. 68 is a cross-sectional view illustrating an example of the cross-sectional structure in a process of manufacturing the memory device according to the third embodiment.

FIG. 69 is a plan view illustrating an example of the planar layout in a process of manufacturing the memory device according to the third embodiment.

FIG. 70 is a cross-sectional view illustrating an example of the cross-sectional structure in a process of manufacturing the memory device according to the third embodiment.

FIG. 71 is a plan view illustrating an example of the planar layout in a process of manufacturing the memory device according to the third embodiment.

FIG. 72 is a cross-sectional view illustrating an example of the cross-sectional structure in a process of manufacturing the memory device according to the third embodiment.

FIG. 73 is a plan view illustrating an example of the planar layout of a memory cell array according to a fourth embodiment.

FIG. 74 is a cross-sectional view taken along line LXXIV-LXXIV of FIG. 73, illustrating an example of the cross-sectional structure of the memory cell array according to the fourth embodiment.

FIG. 75 is a plan view illustrating an example of the planar layout in a process of manufacturing a memory device according to the fourth embodiment.

FIG. 76 is a cross-sectional view illustrating an example of the cross-sectional structure in a process of manufacturing the memory device according to the fourth embodiment.

FIG. 77 is a plan view illustrating an example of the planar layout in a process of manufacturing the memory device according to the fourth embodiment.

FIG. 78 is a cross-sectional view illustrating an example of the cross-sectional structure in a process of manufacturing the memory device according to the fourth embodiment.

FIG. 79 is a plan view illustrating an example of the planar layout in a process of manufacturing the memory device according to the fourth embodiment.

FIG. 80 is a cross-sectional view illustrating an example of the cross-sectional structure in a process of manufacturing the memory device according to the fourth embodiment.

FIG. 81 is a plan view illustrating an example of the planar layout in a process of manufacturing the memory device according to the fourth embodiment v.

FIG. 82 is a cross-sectional view illustrating an example of the cross-sectional structure in a process of manufacturing the memory device according to the fourth embodiment.

FIG. 83 is a plan view illustrating an example of the planar layout in a process of manufacturing the memory device according to the fourth embodiment.

FIG. 84 is a cross-sectional view illustrating an example of the cross-sectional structure in a process of manufacturing the memory device according to the fourth embodiment.

FIG. 85 is a plan view illustrating an example of the planar layout in a process of manufacturing the memory device according to the fourth embodiment.

FIG. 86 is a cross-sectional view illustrating an example of the cross-sectional structure in a process of manufacturing the memory device according to the fourth embodiment.

FIG. 87 is a plan view illustrating an example of the planar layout in a process of manufacturing the memory device according to the fourth embodiment.

FIG. 88 is a cross-sectional view illustrating an example of the cross-sectional structure in a process of manufacturing the memory device according to the fourth embodiment.

### DETAILED DESCRIPTION

In general, according to one embodiment, a memory device includes: a first conductive pillar and a second conductive pillar, each of the first conductive pillar and the second conductive pillar extending in a first direction and arranged in a second direction intersecting the first direction; a first semiconductor layer and a second semiconductor layer, each of the first semiconductor layer and the second semiconductor layer extending in the second direction at a first position in the first direction and sandwiching the first conductive pillar and the second conductive pillar in a third direction intersecting the first direction and the second direction; a first insulator film provided between the first semiconductor layer and the second semiconductor layer and between the first conductive pillar and the second conductive pillar at the first position and having a first portion along a circle centered on the first conductive pillar on a surface facing the first semiconductor layer and the second semiconductor layer; a first charge storage film provided between the first conductive pillar and the first semiconductor layer at the first position; and a second charge storage film provided between the first conductive pillar and the second semiconductor layer at the first position and separated from the first charge storage film.

Hereinafter, embodiments will be described with reference to the drawings. Dimensions and ratios of the drawings are not necessarily the same as actual products.

The following description will use the same reference signs for components having substantially the same functions and configurations. In a case where elements having similar configurations are particularly distinguished from each other, different characters or numbers may be added after their respective reference signs.

### 1. FIRST EMBODIMENT

### 1.1 Configuration

### 1.1.1 Memory System

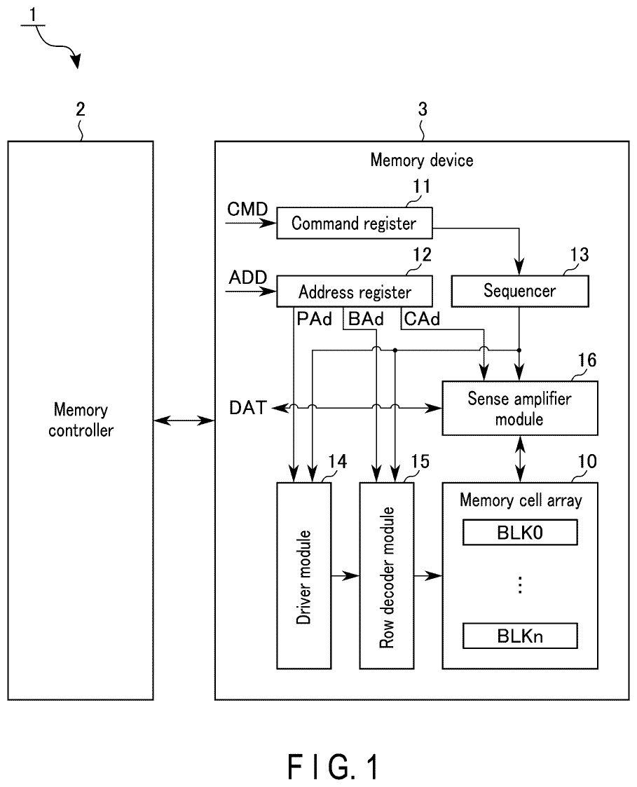

FIG. 1 is a block diagram illustrating an example of the configuration of a memory system including a memory device according to a first embodiment. A memory system 1 is a storage device configured to be connected to an external host (not illustrated). The memory system 1 is, for example, a memory card such as an SD™ card, a universal flash storage (UFS), and a solid state drive (SSD). The memory system 1 includes a memory controller 2 and a memory device 3.

The memory controller 2 includes, for example, an integrated circuit such as a system-on-a-chip (SoC). The memory controller 2 controls the memory device 3 based on a request from the host. Specifically, for example, the memory controller 2 writes data requested to be written by the host into the memory device 3. The memory controller 2 reads data requested to be read from the host from the memory device 3 and transmits the data to the host.

The memory device 3 is a nonvolatile memory. The memory device 3 is, for example, a NAND flash memory. The memory device 3 stores data in a nonvolatile manner.

Communication between the memory controller 2 and the memory device 3 conforms to, for example, a single data rate (SDR) interface, a toggle double data rate (DDR) interface, or an open NAND flash interface (ONFI).

### 1.1.2 Memory Device

Subsequently, the internal configuration of the memory device according to the first embodiment will be described with reference to the block diagram illustrated in FIG. 1. The memory device 3 includes, for example, a memory cell array 10, a command register 11, an address register 12, a sequencer 13, a driver module 14, a row decoder module 15, and a sense amplifier module 16.

The memory cell array 10 includes a plurality of blocks BLK0 to BLKn (n is an integer of 1 or more). The number of blocks BLK included in the memory cell array 10 may be 1. The block BLK is a set of a plurality of memory cells. The block BLK is used, for example, as a data erasing unit. A plurality of bit lines and a plurality of word lines are provided in the memory cell array 10. Each memory cell is associated with, for example, one bit line and one word line. The configuration of the memory cell array 10 will be described in detail later.

The command register 11 stores a command CMD received by the memory device 3 from the memory controller 2. Examples of the command CMD include instructions to cause the sequencer 13 to conduct read, write, and erase operations and the like.

The address register 12 stores address information ADD received by the memory device 3 from the memory controller 2. The address information ADD includes, for example, a block address BAd, a page address PAd, and a column address CAd. For example, the block address BAd, the page address PAd, and the column address CAd are used to select the block BLK, the word line, and the bit line, respectively.

The sequencer 13 controls the entire operation of the memory device 3. For example, the sequencer 13 controls the driver module 14, the row decoder module 15, the sense amplifier module 16, and the like based on the command CMD stored in the command register 11 to execute read, write, and erase operations, and the like.

The driver module 14 generates a voltage used in each of the read, write, and erase operations, and the like. The driver module 14 applies the generated voltage to a signal line corresponding to the selected word line based on, for example, the page address PAd stored in the address register 12.

The row decoder module 15 selects a single corresponding block BLK in the memory cell array 10 based on the block address BAd stored in the address register 12. The row decoder module 15 transfers, for example, the voltage applied to the signal line corresponding to the selected word line to the selected word line in the selected block BLK.

The sense amplifier module 16 in the write operation applies a desired voltage to each bit line according to write data DAT received from the memory controller 2. The sense amplifier module 16 in the read operation determines data stored in a memory cell based on the voltage of the bit line and transfers the result of determination to the memory controller 2 as read data DAT.

### 1.1.3 Memory Cell Array

### <Circuit Configuration>

Next, the circuit configuration of the memory cell array according to the first embodiment will be described.

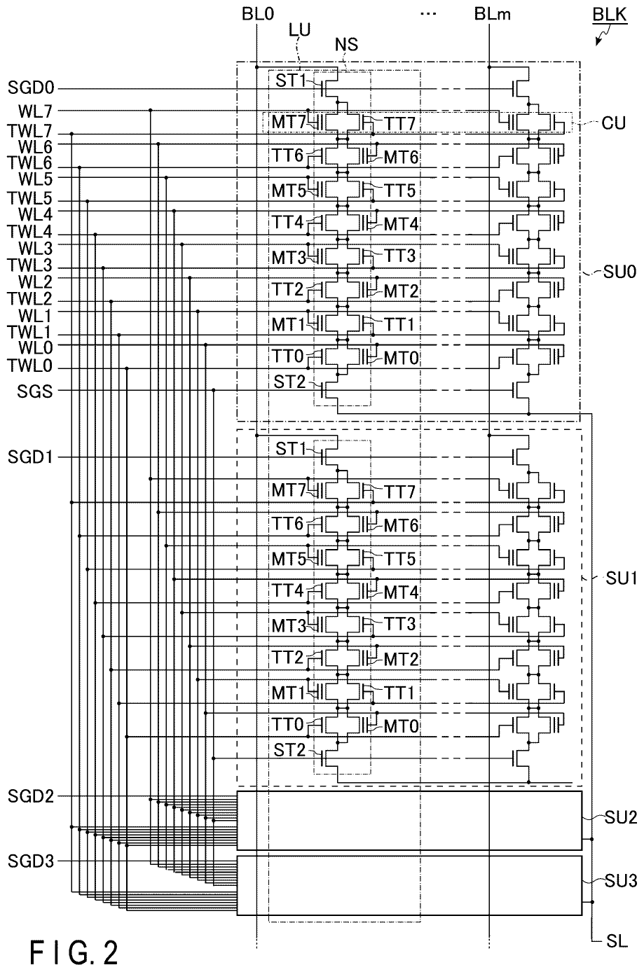

FIG. 2 is a circuit diagram illustrating an example of the circuit configuration of the memory cell array included in the memory device according to the first embodiment. FIG. 2 illustrates one of the plurality of blocks BLK included in the memory cell array 10. As illustrated in FIG. 2, the block BLK includes, for example, four string units SU0 to SU3.

Each string unit SU includes a plurality of NAND strings NS associated with respective bit lines BL0 to BLm (m is an integer of 1 or more). The number of the bit lines BL may be 1. Each of the NAND strings NS includes, for example, memory cell transistors MT0 to MT7, transfer transistors TT0 to TT7, and select transistors ST1 and ST2. Each of the memory cell transistors MT includes a control gate and a charge storage film, and stores data in a nonvolatile manner. Each of the transfer transistors TT includes a control gate and is used to form an auxiliary current path (channel) between the memory cell transistors MT adjacent in the NAND string NS. The select transistors ST1 and ST2 are used to select an applicable string unit SU during various operations.

In each of the NAND strings NS, the memory cell transistors MT0 to MT7 are connected in series. The select transistor ST1 has its drain connected to the associated bit line BL. The source of the select transistor ST1 is connected to one end of the memory cell transistors MT0 to MT7 connected in series. The select transistor ST2 has its drain connected to the other end of the memory cell transistors MT0 to MT7 connected in series. The source of the select transistor ST2 is connected to the source line SL. The transfer transistors TT0 to TT7 are connected in parallel with the memory cell transistors MT0 to MT7, respectively. The transfer transistor TT prevents a current from unintentionally flowing through the NAND string NS or prevents a current from unintentionally non-flowing through the NAND string NS.

In the same block BLK, the control gates of the memory cell transistors MT0 to MT7 are connected to word lines WL0 to WL7, respectively. The control gates of the transfer transistors TT0 to TT7 are connected to word lines TWL0 to TWL7, respectively. The gate of the select transistor ST1 in the string units SU0 to SU3 is connected to select gate lines SGD0 to SGD3, respectively. The gates of the plurality of select transistors ST2 are connected to a select gate line SGS.

Different column addresses are allocated to the bit lines BL0 to BLm. Each of the bit lines BL is shared by the NAND strings NS to which the same column address is allocated among the plurality of blocks BLK. Each of the word lines WL0 to WL7 and TWL0 to TWL7 is provided for each block BLK. The source line SL is shared among the plurality of blocks BLK, for example.

A set of the plurality of memory cell transistors MT connected to a common word line WL in one string unit SU is referred to as, for example, a cell unit CU. For example, the storage capacity of the cell unit CU including the memory cell transistors MT each storing 1-bit data is defined as “1-page data”. The cell unit CU may have a storage capacity of 2-page data or more according to the number of bits of data stored in the memory cell transistors MT.

A set of the plurality of memory cell transistors MT and transfer transistors TT connected to a common bit line BL in one block BLK is referred to as, for example, a layer unit LU. One layer unit LU includes four NAND strings NS. The four NAND strings NS included in one layer unit LU belong to the string units SU0 to SU3, respectively.

Note that the circuit configuration of the memory cell array 10 included in the memory device 3 is not limited to the configuration described above. For example, the number of the string units SU included in each block BLK may be discretionarily designed. The numbers of the memory cell transistors MT, the transfer transistors TT, and the select transistors ST1 and ST2 included in each NAND string NS may be discretionarily designed.

### <Planar Layout>

Next, the planar layout of the memory cell array according to the first embodiment will be described.

The memory cell array 10 is provided above a substrate. Hereinafter, a plane parallel to the surface of the substrate is referred to as an XY plane. Directions intersecting each other in the XY plane are defined as an X direction and a Y direction. A direction from the substrate toward the memory cell array is defined as a Z direction. The Z direction may be read as an upward direction.

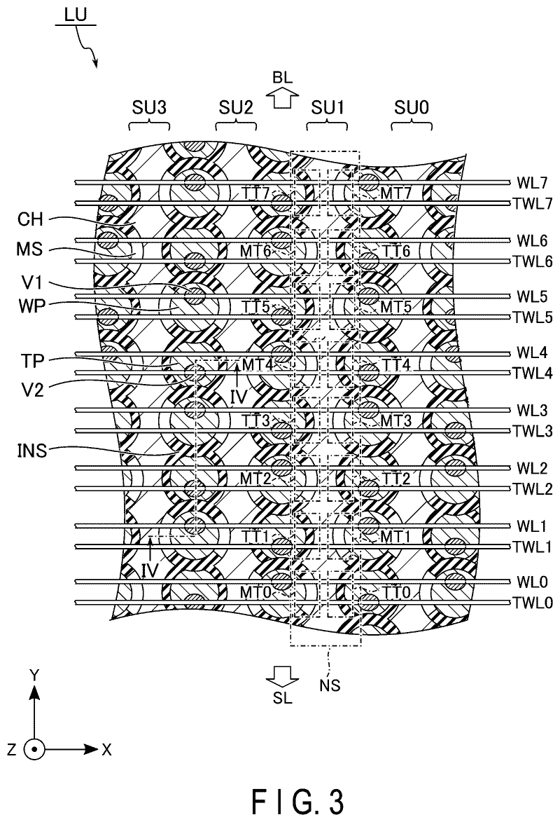

FIG. 3 is a plan view illustrating an example of the planar layout of the memory cell array according to the first embodiment. FIG. 3 illustrates a plan view of a position where the position in the Z direction is substantially equal to the substrate in the structure constituting the memory cell array 10. The position includes a structure functioning as the NAND string NS. A portion illustrated in FIG. 3 corresponds to one layer unit LU in the circuit diagram illustrated in FIG. 2.

As illustrated in FIG. 3, in the same layer, the memory cell array 10 includes a plurality of conductive pillars WP and TP, a plurality of memory structures MS, a plurality of insulators INS, a channel structure CH, a plurality of word lines WL and TWL, and a plurality of contacts V1 and V2.

Each of the plurality of conductive pillars WP and TP is a conductor having a columnar shape extending in the Z direction. The plurality of conductive pillars WP and TP are disposed in square on the XY plane. Specifically, the conductive pillars WP and TP arranged in the same row in the X direction are alternately disposed. The conductive pillars WP and TP arranged in the same row in the Y direction are disposed successively one by one (alternately). That is, any conductive pillar WP is sandwiched between the two conductive pillars TP adjacent in the X direction and between the two conductive pillars TP adjacent in the Y direction. Similarly, any conductive pillar TP is sandwiched between the two conductive pillars WP adjacent in the X direction and between the two conductive pillars WP adjacent in the Y direction.

Each of the plurality of insulators INS is an insulator surrounding the outer periphery of the corresponding conductive pillar TP. The insulator INS surrounds a part of the outer peripheries of the two conductive pillars WP adjacent to the corresponding conductive pillar TP in the Y direction. In other words, the insulator INS has a portion along a circle centered on the conductive pillar WP on the surface facing the channel structure CH. That is, the insulator INS has a portion formed concentrically around the corresponding conductive pillar TP and a portion formed concentrically around each of the two conductive pillars WP arranged with the conductive pillar TP in the Y direction. The conductive pillars WP and the conductive pillars TP are alternately arranged in the Y direction in the same row with the insulator INS interposed therebetween. As a result, the insulator INS insulates the conductive pillar TP from the two conductive pillars WP adjacent to the conductive pillar TP in the Y direction.

Each of the plurality of memory structures MS is a stacked film corresponding to the gate structure of the memory cell transistor MT. The two memory structures MS are disposed corresponding to one conductive pillar WP. Specifically, the two memory structures MS are provided on the outer periphery of the conductive pillar WP away from each other with the insulator INS interposed therebetween. That is, the two memory structures MS corresponding to the conductive pillar WP are arranged in the X direction so as to sandwich the conductive pillar WP.

Structures in which the conductive pillar WP including the two memory structures MS partially arranged on the outer periphery and the conductive pillar TP including the insulator INS surrounding the outer periphery are repeatedly arranged in this order in the Y direction (hereinafter, also referred to as “row structures”) are arranged in the X direction. In the example of FIG. 3, an example in which the five row structures are arranged in the X direction is illustrated.

Each of the plurality of channel structures CH is a semiconductor extending in the Y direction. The channel structure CH is disposed between the two row structures adjacent in the X direction. Note that the plurality of channel structures CH may be divided from each other at both ends in the Y direction, or may be connected to each other with the select transistors ST1 and ST2 (not illustrated) interposed therebetween.

The memory structure MS and the portions of the conductive pillar WP and the channel structure CH sandwiching the memory structure MS function as one memory cell transistor MT. The portion of the insulator INS, and the portions of the conductive pillar TP and the channel structure CH sandwiching the portion of the insulator INS function as the transfer transistor TT. The channel structure CH and a portion in contact with the channel structure CH in the two row structures sandwiching the channel structure CH constitute one NAND string NS. In FIG. 3, four NAND strings NS formed by five row structures arranged in the X direction and four channel structures CH disposed between the five row structures correspond to the string units SU0 to SU3, respectively.

One end of the NAND string NS in the Y direction is connected to the bit line BL with the select transistor ST1 (not illustrated) interposed therebetween. The other end of the NAND string NS in the Y direction is connected to the source line SL with the select transistor ST2 (not illustrated) interposed therebetween.

Each of the plurality of word lines WL and TWL extends in the X direction. The plurality of word lines WL and TWL are arranged in the Y direction. The word line WL is disposed at a position overlapping the plurality of conductive pillars WP arranged in the X direction as viewed in the Z direction. The conductive pillar WP is connected to the corresponding word line WL via the contact V1. The word line TWL is disposed at a position overlapping the plurality of conductive pillars TP arranged in the X direction as viewed in the Z direction. The conductive pillar TP is connected to the corresponding word line TWL via the contact V2.

### <Cross-Sectional Structure>

Next, the cross-sectional structure of the memory cell array according to the first embodiment will be described.

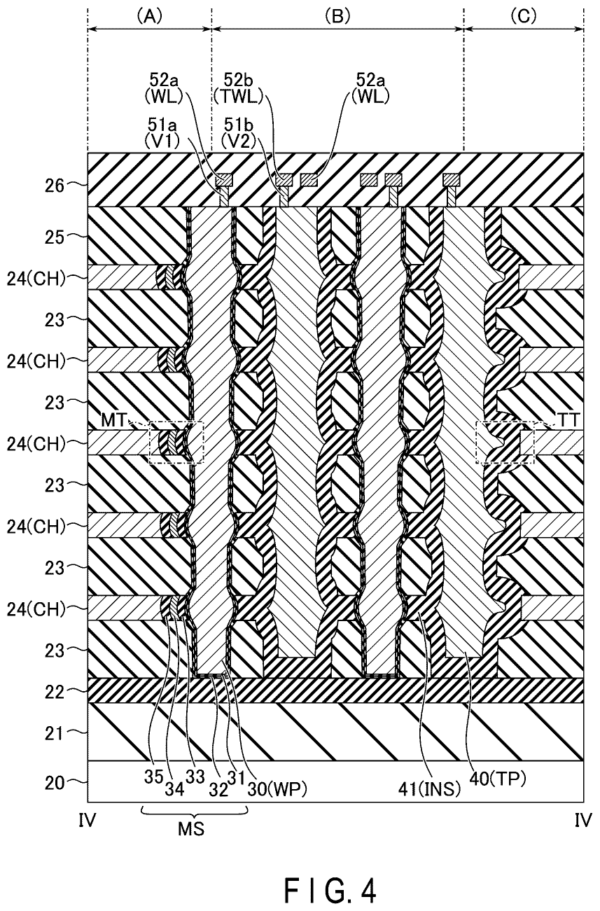

FIG. 4 is a cross-sectional view taken along line IV-IV of FIG. 3, illustrating an example of the cross-sectional structure of the memory cell array according to the first embodiment. FIG. 4 mainly illustrates a cross-sectional structure of a portion (A) where the channel structure CH and the conductive pillar WP are adjacent in the X direction with the memory structure MS interposed therebetween, a cross-sectional structure of a portion (B) where the conductive pillars WP and TP are adjacent in the Y direction, and a cross-sectional structure of a portion (C) where the channel structure CH and the conductive pillar TP are adjacent in the X direction with the insulator INS interposed therebetween.

As illustrated in FIG. 4, the memory cell array 10 includes a substrate 20, insulating layers 21, 22, 23, 25, and 26, a semiconductor layer 24, conductor films 30 and 40, insulator films 31, 32, 33, 35, and 41, a charge storage film 34, and conductive layers 51a, 51b, 52a, and 52b.

The substrate 20 is, for example, a P-type semiconductor. The insulating layer 21 is provided on the upper surface of the substrate 20. The substrate 20 and the insulating layer 21 may include a circuit (not illustrated). The circuits included in the substrate 20 and the insulating layer 21 correspond to, for example, the row decoder module 15, the sense amplifier module 16, and the like.

The insulating layer 22 is provided on the upper surface of the insulating layer 21. The insulating layer 22 functions as a stop film in a case where a structure corresponding to the memory cell array 10 provided above is processed.

On the upper surface of the insulating layer 22, the plurality of insulating layers 23 and the plurality of semiconductor layers 24 are alternately stacked one by one. In the example of FIG. 4, the five insulating layers 23 and the five semiconductor layers 24 are alternately stacked one by one. In other words, the plurality of semiconductor layers 24 stacked apart in the Z direction are provided above the substrate 20. The number of the stacked semiconductor layers 24 corresponds to, for example, the number of the bit lines BL.

The insulating layer 23 contains, for example, silicon oxide. The semiconductor layer 24 contains, for example, polysilicon. The semiconductor layer 24 corresponds to the channel structure CH and functions as the current path of the NAND string NS.

The insulating layer 25 is provided on the upper surface of the semiconductor layer 24 as an uppermost layer. The insulating layer 26 is provided on the upper surface of the insulating layer 25. The insulating layers 25 and 26 contain, for example, silicon oxide.

The conductor film 30 is a conductor extending in the Z direction so as to cross the plurality of semiconductor layers 24, and functions as the conductive pillar WP. The lower end of the conductor film 30 is located below the semiconductor layer 24 as a lowermost layer and above the insulating layer 22. The upper end of the conductor film 30 is aligned with, for example, the upper end of the insulating layer 25. The conductor film 30 contains, for example, titanium nitride.

The insulator film 31 covers the lower surface and the side surface of the conductor film 30. The insulator film 32 covers the lower surface and the side surface of the insulator film 31. The lower end of the insulator film 32 is in contact with, for example, the insulating layer 22. The insulator film 33 is provided on a portion facing the semiconductor layer 24 of the side surface of the insulator film 32. The insulator film 33 is provided between the two insulating layers 23 sandwiching the corresponding semiconductor layer 24 in the Z direction or between the insulating layers 23 and 25. The insulator film 31 contains, for example, aluminum oxide. The insulator film 32 contains, for example, silicon oxide. The insulator film 33 contains, for example, hafnium silicate. The insulator films 31, 32, and 33 function as a block insulating film of the memory cell transistor MT.

The charge storage film 34 is provided on the side surface of the insulator film 33 and is located between the insulator film 33 and the semiconductor layer 24. The charge storage film 34 is provided between the two insulating layers 23 sandwiching the corresponding semiconductor layer 24 in the Z direction or between the insulating layers 23 and 25. The charge storage film 34 contains a material having a function of storing charges. Specifically, the charge storage film 34 may contain, for example, a conductor such as silicon or metal. The charge storage film 34 may contain an insulator such as silicon nitride, for example. In a case where the charge storage film 34 contains a conductor such as silicon or metal, the charge storage film 34 functions as a floating gate of a floating gate type memory cell transistor MT. In a case where the charge storage film 34 contains an insulator such as silicon nitride, the charge storage film 34 functions as a charge trap film of a metal-oxide-nitride-oxide-silicon (MONOS) type memory cell transistor MT.

The insulator film 35 is provided on the side surface of the charge storage film 34 and located between the charge storage film 34 and the semiconductor layer 24. The insulator film 35 is provided between the two insulating layers 23 sandwiching the corresponding semiconductor layer 24 in the Z direction or between the insulating layers 23 and 25. The insulator film 35 contains, for example, silicon oxide. The insulator film 35 functions as a tunnel insulating film of the memory cell transistor MT.

The insulator films 31, 32, 33, and 35 and the charge storage film 34 as described above function as the memory structure MS of the memory cell transistor MT.

The conductor film 40 is a conductor extending in the Z direction so as to cross the plurality of semiconductor layers 24, and functions as the conductive pillar TP. The lower end of the conductor film 40 is located below the semiconductor layer 24 as a lowermost layer and above the insulating layer 22. The upper end of the conductor film 40 is aligned with, for example, the upper end of the insulating layer 25. The conductor film 40 contains, for example, titanium nitride.

The insulator film 41 covers the lower surface and the side surface of the conductor film 40. A portion of the insulator film 41 facing the semiconductor layer 24 functions as a gate insulating film of the transfer transistor TT. The insulator film 41 is continuous with a portion in contact with the insulator film 32 covering the conductive pillars WP (that is, a portion functioning as the insulator INS) at the same position as that of each of the plurality of semiconductor layers 24 in the Z direction. The portion of the insulator film 41 that functions as the insulator INS at the same position as that of each of the plurality of semiconductor layers 24 in the Z direction is a portion that expands in a radial direction as viewed in the Z direction with respect to the portion of the insulator film 41 extending in the Z direction, and is provided between the two insulating layers 23 or the insulating layers 23 and 25. Therefore, the length (film thickness) in the Z direction of the portion of the insulator film 41 in contact with the insulator film 32 covering the conductive pillars WP is substantially equal to the film thickness of the semiconductor layer 24, and there is no portion longer than the film thickness of the semiconductor layer 24. The insulator film 41 contains, for example, silicon oxide.

On the upper surface of the conductor film 30, the conductive layer 51a functioning as the contact V1 is provided. On the upper surface of the conductive layer 51a, the conductive layer 52a functioning as the word line WL is provided. The conductive layer 52a contains, for example, copper.

On the upper surface of the conductor film 40, the conductive layer 51b functioning as the contact V2 is provided. On the upper surface of the conductive layer 51b, the conductive layer 52b functioning as the word line TWL is provided. The conductive layer 52b contains, for example, copper.

### 1.2 Producing Method

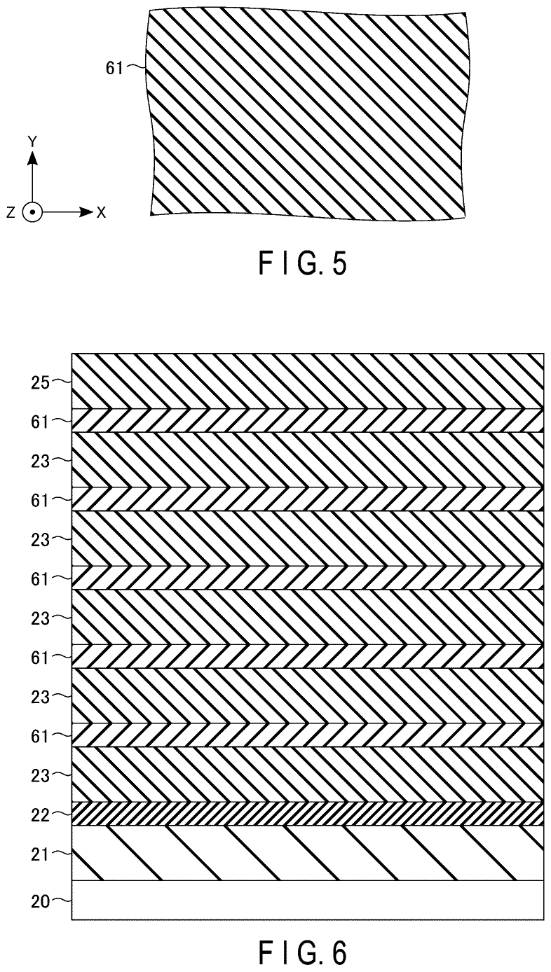

FIGS. 5, 7, 9, 11, 13, 15, 17, 19, 21, 23, and 25 are plan views illustrating an example of the planar layout of the memory device according to the first embodiment under production. FIGS. 6, 8, 10, 12, 14, 16, 18, 20, 22, 24, and 26 are cross-sectional views illustrating an example of the cross-sectional structure of the memory device according to the first embodiment under production. Each of the cross-sectional views illustrated in FIGS. 6, 8, 10, 12, 14, 16, 18, 20, 22, 24, and 26 corresponds to a cross section cut at the same position as that of line IV-IV illustrated in FIG. 3 in the planar layout illustrated in FIGS. 5, 7, 9, 11, 13, 15, 17, 19, 21, 23, and 25.

First, as illustrated in FIGS. 5 and 6, a stacked structure is formed on the upper surface of the substrate 20. Specifically, the insulating layers 21 and 22 are stacked in this order on the upper surface of the substrate 20. Subsequently, the insulating layer 23 and a sacrificial member 61 are repeatedly stacked in this order on the upper surface of the insulating layer 22. The insulating layer 25 is provided on the upper surface of the sacrificial member 61 as an uppermost layer. The sacrificial member 61 contains, for example, silicon nitride.

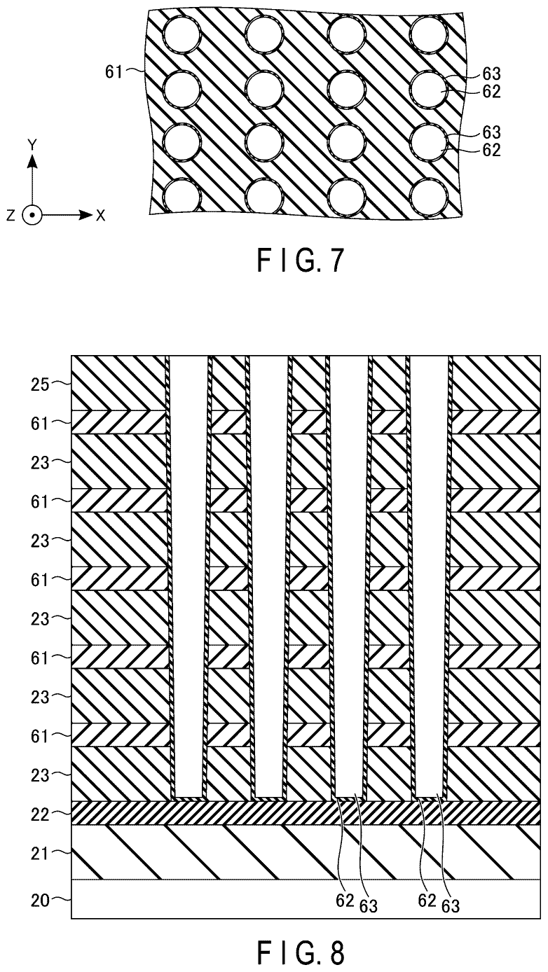

Next, as illustrated in FIGS. 7 and 8, an insulator film 62 and a sacrificial member 63 are provided in a region where the plurality of conductive pillars WP and TP are to be provided in the stacked structure. Specifically, a plurality of holes are provided in the region where the plurality of conductive pillars WP and TP are to be provided. Specifically, the plurality of holes are provided so as to be disposed in square as viewed in the Z direction. Each of the plurality of holes penetrates the insulating layer 25, the plurality of sacrificial members 61, and the plurality of insulating layers 23. The bottom of each of the plurality of holes reaches the insulating layer 22.

The thin insulator film 62 is formed inside each of the plurality of holes. Thereafter, each of the plurality of holes is embedded by the sacrificial member 63. The insulator film 62 contains, for example, silicon oxide. The sacrificial member 63 contains, for example, polysilicon.

Here, the plurality of holes are formed so as not to interfere with each other at any position in the Z direction. Therefore, at the position where the insulating layer 23, the sacrificial member 61, and the insulating layer 25 are provided in the Z direction, the insulating layer 23, the sacrificial member 61, and the insulating layer 25 exist between the plurality of holes arranged in the Y direction, respectively.

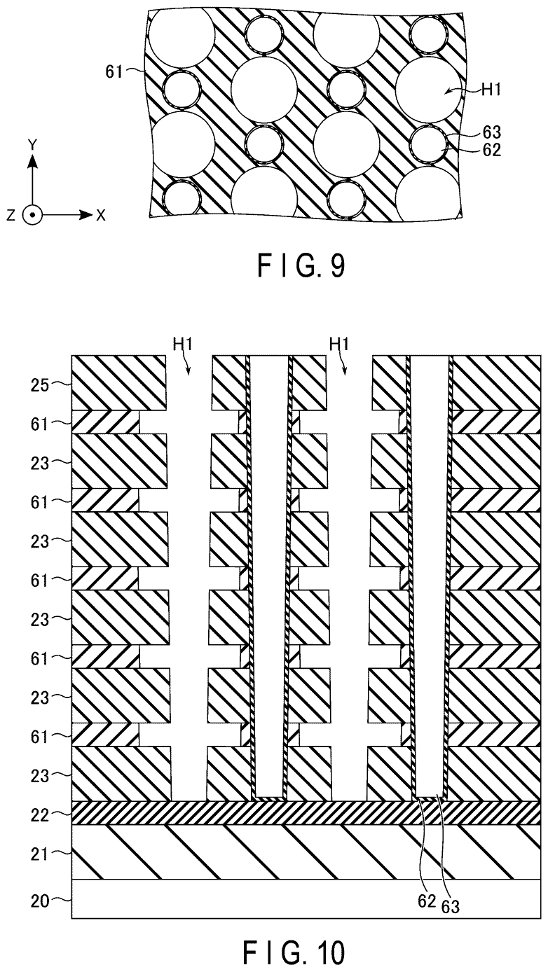

Next, as illustrated in FIGS. 9 and 10, the sacrificial member 63 and the insulator film 62 provided in the region corresponding to the conductive pillar WP are removed to form a plurality of holes H1. As a result, the plurality of sacrificial members 61 stacked apart from each other are exposed inside the plurality of holes H1.

Thereafter, the sacrificial member 61 is partially removed from the plurality of holes H1. As a result, a groove extending concentrically from the centers of the plurality of holes H1 is formed for each layer provided with the sacrificial member 61. Each of the plurality of grooves formed in the hole H1 is formed with a depth that does not reach the insulator film 62 adjacent to the hole H1 in the Y direction. In other words, the insulator film 62 is not exposed inside the groove formed in the hole H1.

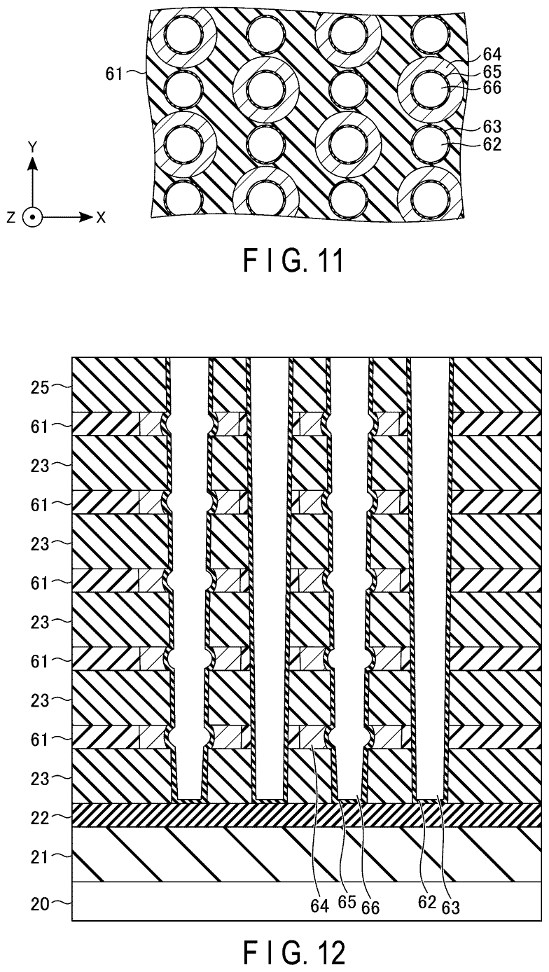

Next, as illustrated in FIGS. 11 and 12, the plurality of holes H1 are embedded by the sacrificial member 64, the insulator film 65, and the sacrificial member 66.

Specifically, the plurality of grooves formed in each of the plurality of holes H1 are embedded by the sacrificial member 64. The thin insulator film 65 is formed inside each of the plurality of holes H1. Thereafter, each of the plurality of holes H1 is embedded by the sacrificial member 66. The sacrificial member 64 contains, for example, amorphous silicon. The insulator film 65 contains, for example, silicon oxide. The sacrificial member 66 contains, for example, polysilicon.

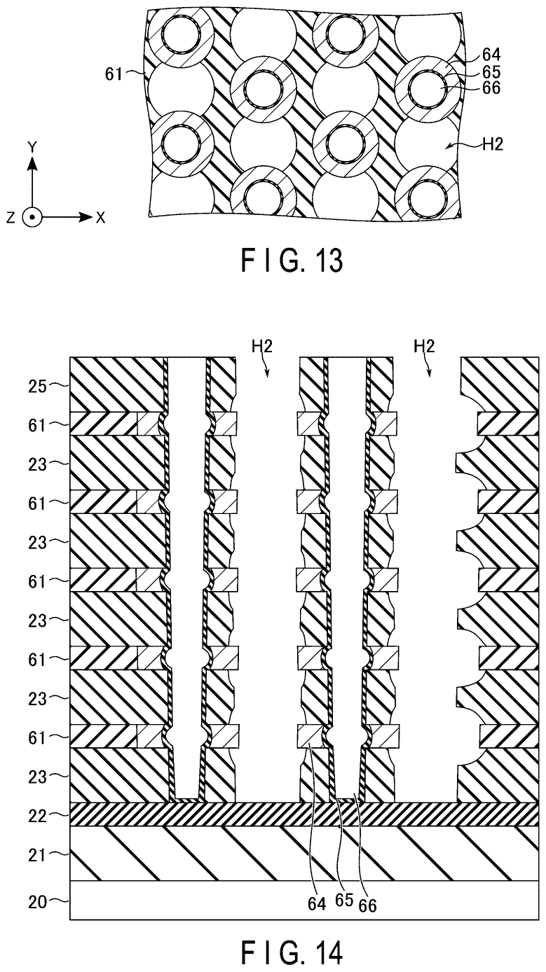

Next, as illustrated in FIGS. 13 and 14, the sacrificial member 63 and the insulator film 62 provided in the region corresponding to the conductive pillar TP are removed to form a plurality of holes H2. As a result, the plurality of sacrificial members 61 stacked apart from each other are exposed inside the plurality of holes H2.

Thereafter, the sacrificial member 61 is partially removed from the plurality of holes H2. As a result, a groove extending concentrically from the centers of the plurality of holes H2 is formed for each layer provided with the sacrificial member 61. The groove formed in the hole H2 is formed, for example, at the same depth as that of the groove (embedded by the sacrificial member 64) formed in the hole H1. In the groove formed in the hole H2, the sacrificial member 64 adjacent in the Y direction is exposed, but the sacrificial member 64 adjacent in the X direction is not exposed.

Thereafter, the insulating layers 23 and 25 are partially removed from the plurality of holes H2. As a result, the insulating layers 23 and 25 are removed from the groove formed in the hole H2. Therefore, the groove formed in the hole H2 is larger in the Z direction than the film thickness of the sacrificial member 61. In other words, the plurality of insulating layers 23 and 25 are thinned.

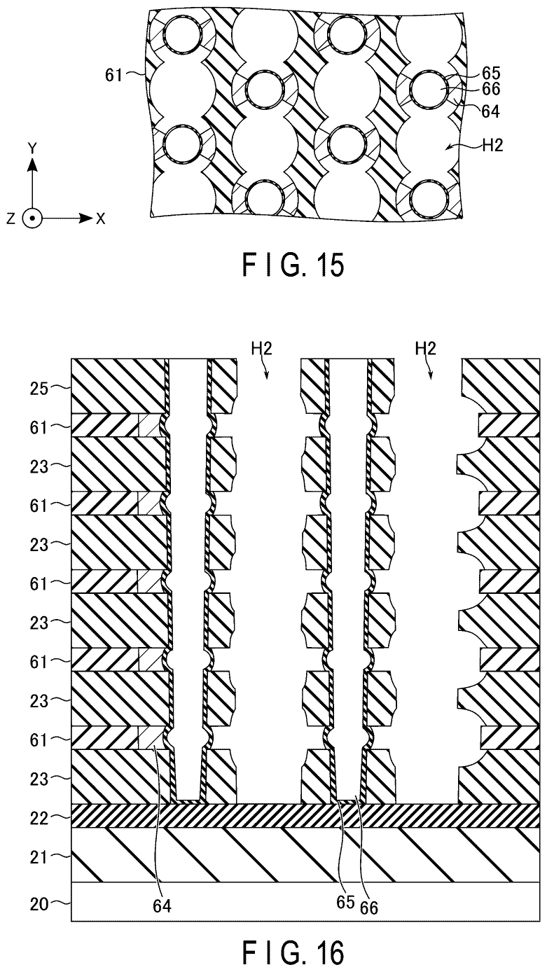

Next, as illustrated in FIGS. 15 and 16, the sacrificial member 64 is partially removed from the plurality of holes H2. As a result, the sacrificial member 64 is divided into two portions sandwiching the sacrificial member 66 in the X direction. That is, the portion of the insulator film 65 facing the hole H2 is exposed inside the hole H2 at the position where the sacrificial member 64 is formed in the Z direction. A region where the sacrificial member 64 divided into two portions remains corresponds to a region where the memory structure MS is to be provided.

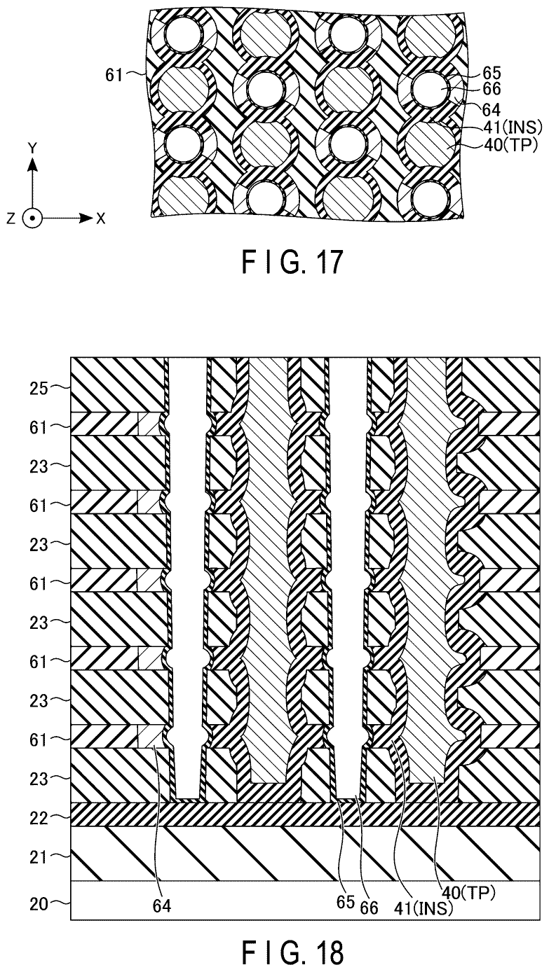

Next, as illustrated in FIGS. 17 and 18, the plurality of holes H2 are embedded by the insulator film 41 and the conductor film 40. Specifically, the groove formed by removing the sacrificial member 64 is embedded by the insulator film 41. Thereafter, the plurality of holes H2 are embedded by the conductor film 40. The insulator film 41 provided between the conductor film 40 and the sacrificial member 61 functions as a gate insulating film of the transfer transistor TT.

As described above, the groove where the sacrificial member 61 in the hole H2 is exposed is enlarged in the Z direction by removing the insulating layers 23 and 25, and thus is not closed by the insulator film 41. In this manner, the film thickness of the gate insulating film of the transfer transistor TT is adjusted so as not to excessively increase.

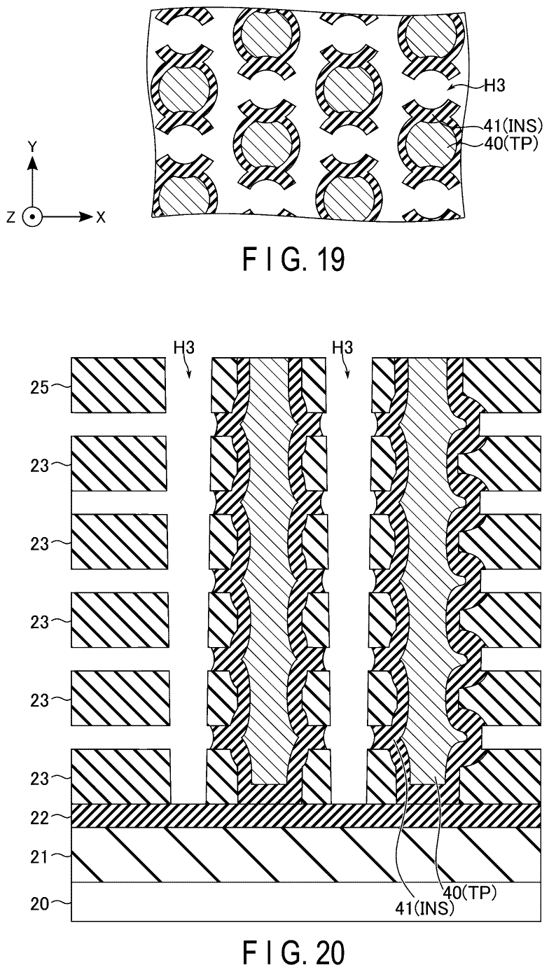

Next, as illustrated in FIGS. 19 and 20, the sacrificial member 66 and the insulator film 65 provided in the region corresponding to the conductive pillar WP are removed to form a plurality of holes H3. The plurality of sacrificial members 64 stacked apart from each other are exposed inside the plurality of holes H3. Subsequently, the plurality of sacrificial members 64 are removed from the plurality of holes H3. As a result, a plurality of grooves are formed in each of the plurality of holes H3. The sacrificial member 61 is exposed inside each of the plurality of grooves. Subsequently, the plurality of sacrificial members 61 are removed from the plurality of grooves formed in each of the plurality of holes H3. As a result, the plurality of holes H3 are connected in one via the plurality of grooves.

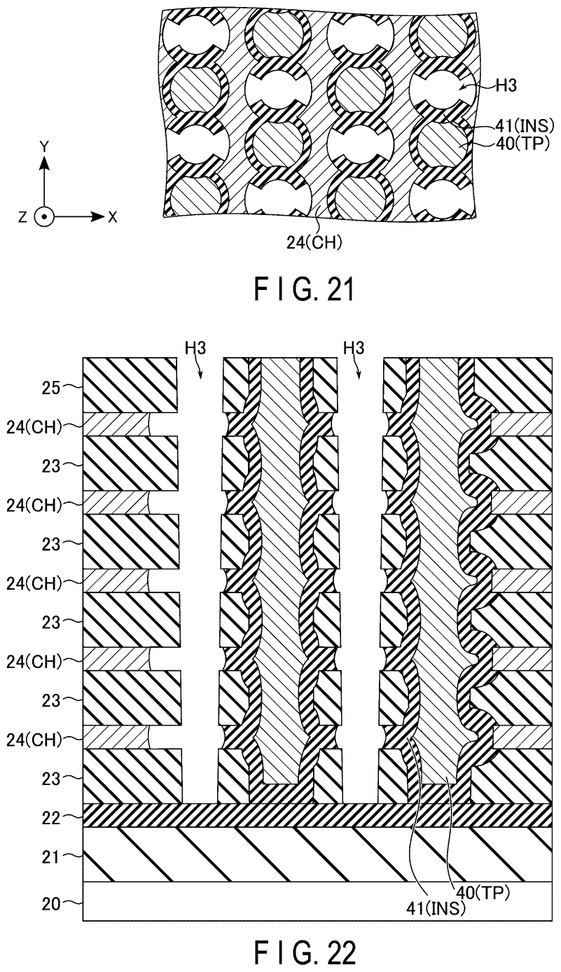

Next, as illustrated in FIGS. 21 and 22, the semiconductor layer 24 is formed via the plurality of holes H3 connected in one via the plurality of grooves. As a result, a region where the channel structure CH is to be formed in the plurality of grooves formed in each of the plurality of holes H3 is embedded by the semiconductor layer 24. The plurality of holes H3 are divided again by the semiconductor layer 24.

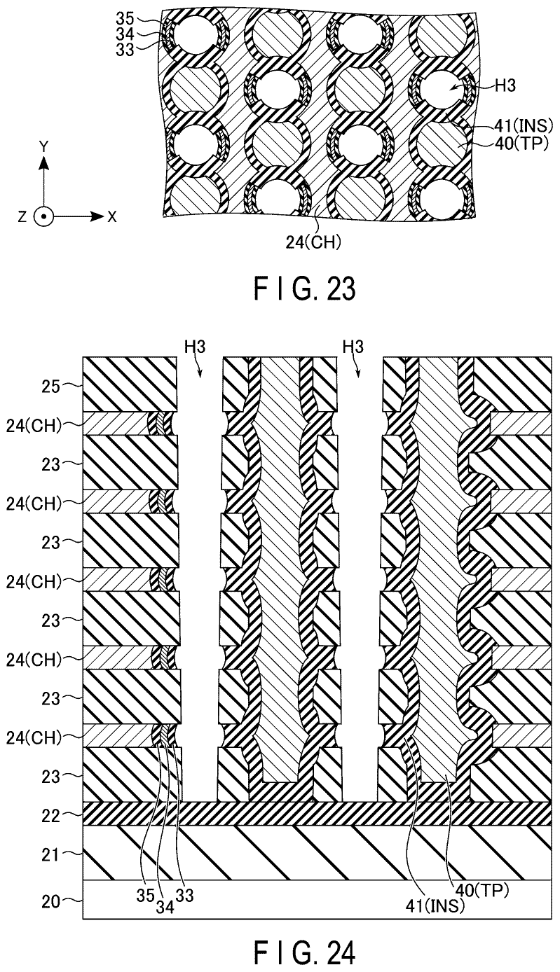

Next, as illustrated in FIGS. 23 and 24, the insulator film 35, the charge storage film 34, and the insulator film 33 are formed via the plurality of holes H3. As a result, each of the plurality of grooves formed in each of the plurality of holes H3 is embedded by the stacked film of the insulator film 35, the charge storage film 34, and the insulator film 33.

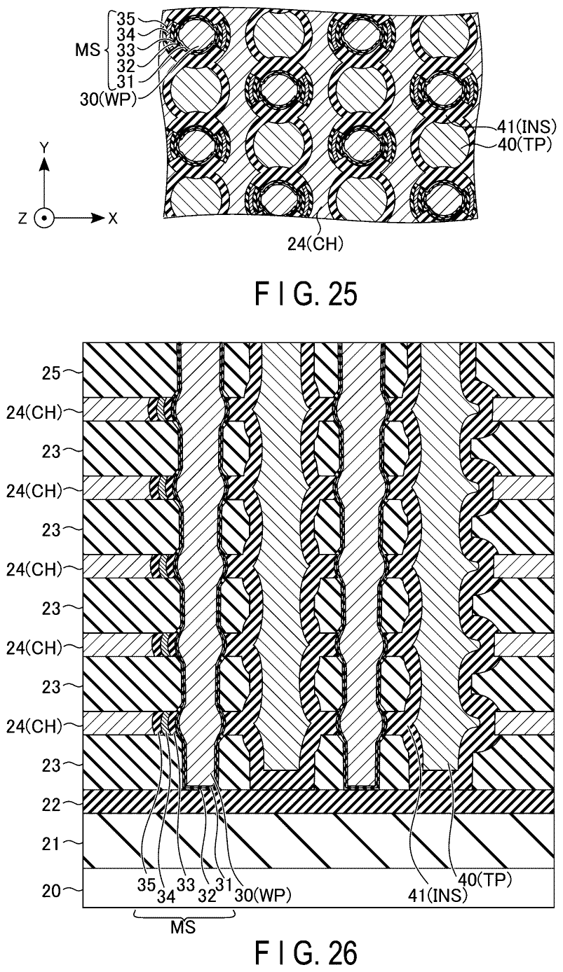

Next, as illustrated in FIGS. 25 and 26, the insulator film 32, the insulator film 31, and the conductor film 30 are formed via the plurality of holes H3 to embed the plurality of holes H3.

Thereafter, a structure above the stacked structure of the memory cell array 10 is formed. Thus, a memory device 3 is formed.

### 1.3 Effects According to First Embodiment

According to the first embodiment, the region where the plurality of holes corresponding to the conductive pillars WP and TP are formed has a stacked structure of the insulating layer 23 and the sacrificial member 61. As a result, for example, in the region where the plurality of holes corresponding to the conductive pillars WP and TP are formed, the processing becomes easier than in a case where the region where the stacked structure of the silicon oxide layer and the silicon nitride layer is processed and the region where the stacked structure including only the silicon oxide layer is processed are mixed. Therefore, an increase in the producing cost of the memory device 3 can be suppressed.

The plurality of holes corresponding to the conductive pillars WP and TP are collectively formed. As a result, the step of processing the stacked structure of the insulating layer 23 and the sacrificial member 61 in the Z direction can be performed once. Therefore, an increase in the producing cost of the memory device 3 can be suppressed.

The NAND string NS includes the memory cell transistor MT formed around the conductive pillar WP and the transfer transistor TT formed around the conductive pillar TP. As a result, current control in the NAND string NS can be facilitated, and interference between the facing memory cell transistors MT can be reduced.

### 1.4 Modification of First Embodiment

Various modifications can be applied to the above-described first embodiment.

For example, in the first embodiment described above, the case where the memory cell transistor MT and the transfer transistor TT are provided in the NAND string NS has been described, but the present invention is not limited thereto. For example, the transfer transistor TT may not be provided.

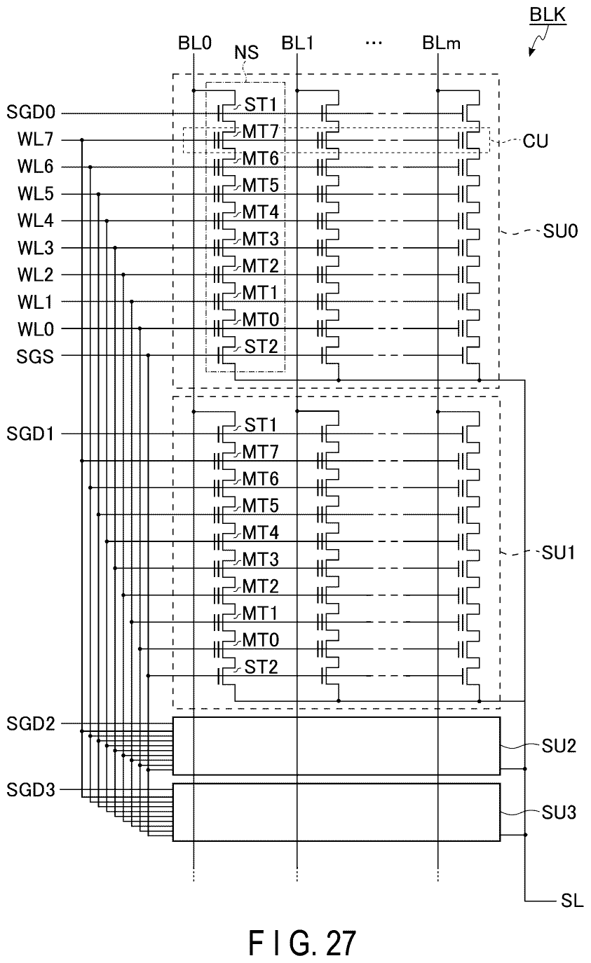

FIG. 27 is a circuit diagram illustrating an example of the circuit configuration of a memory cell array included in a memory device according to a modification of the first embodiment. FIG. 27 corresponds to FIG. 2 in the first embodiment.

As illustrated in FIG. 27, the NAND string NS may be configured without including the transfer transistor TT. Specifically, the NAND string NS may include a plurality of memory cell transistors MT0 to MT7 connected in series, and select transistors ST1 and ST2 provided at both ends of the plurality of memory cell transistors MT, respectively. In this case, the conductive pillar TP may be replaced with an insulating pillar RP made of an insulating material.

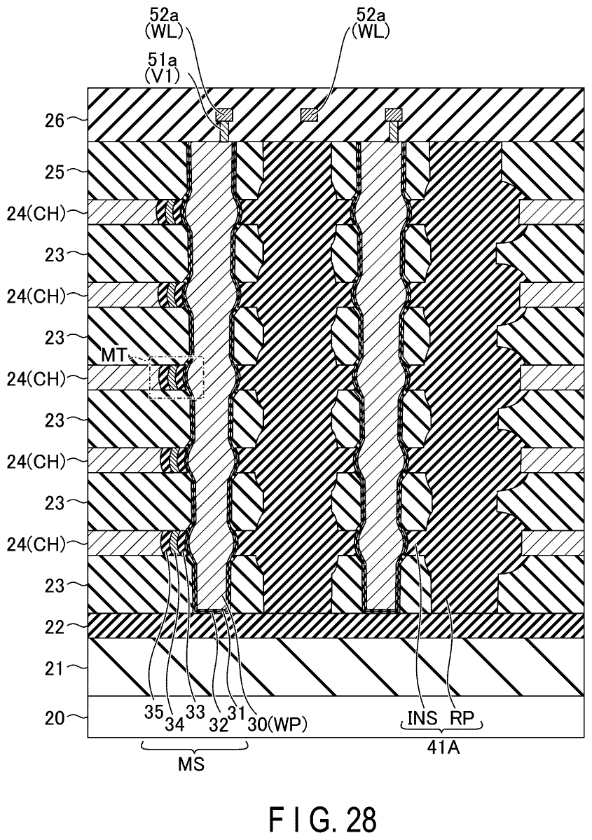

FIG. 28 is a cross-sectional view illustrating an example of the cross-sectional structure of the memory cell array according to the modification of the first embodiment. FIG. 28 corresponds to FIG. 4 in the first embodiment.

As illustrated in FIG. 28, in the first embodiment, the conductor film 40 and the insulator film 41 may be replaced with an insulator film 41A. The insulator film 41A is formed by collectively filling a plurality of grooves formed in a hole H2 and the hole H2 itself. In this case, the insulator film 41A further has a portion along a circle centered on the insulating pillar RP on a surface facing a semiconductor layer 24.

Also with the above configuration, similarly to the first embodiment, it is possible to form a structure in which the NAND strings NS extending in the horizontal direction with respect to the substrate 20 is stacked in the Z direction while suppressing the step of processing the stacked structure on the substrate 20 in the Z direction at a time.

### 2. SECOND EMBODIMENT

Next, a memory device according to a second embodiment will be described. The memory device according to the second embodiment is different from that of the first embodiment in that memory cells are formed for all holes obtained by processing a stacked structure on a substrate 20 in a Z direction. Hereinafter, a configuration and a producing method different from those of the first embodiment will be mainly described. The descriptions of the same configuration and producing method as those of the first embodiment will be appropriately omitted.

### 2.1 Configuration

### <Circuit Configuration>

First, the circuit configuration of a memory cell array according to the second embodiment will be described.

The circuit configuration of a memory cell array 10 in the second embodiment is the same as the circuit configuration of the memory cell array 10 in the modification of the first embodiment. That is, a NAND string NS included in the memory cell array 10 includes a plurality of memory cell transistors MT0 to MT7 connected in series, and select transistors ST1 and ST2 provided at both ends of the plurality of memory cell transistors MT, respectively.

### <Planar Layout>

Next, the planar layout of the memory cell array according to the second embodiment will be described.

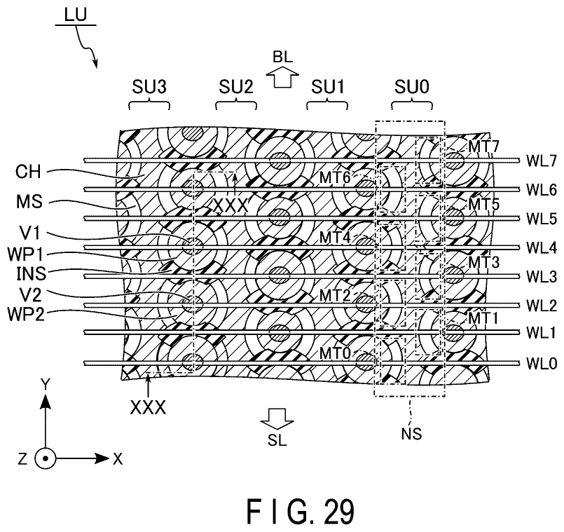

FIG. 29 is a plan view illustrating an example of the planar layout of the memory cell array according to the second embodiment. FIG. 29 corresponds to FIG. 3 in the first embodiment.

As illustrated in FIG. 29, in the same layer, the memory cell array 10 includes a plurality of conductive pillars WP1 and WP2, a plurality of memory structures MS, a plurality of insulators INS, a channel structure CH, a plurality of word lines WL, and a plurality of contacts V1 and V2.

Each of the plurality of conductive pillars WP1 and WP2 is a conductor having a columnar shape extending in the Z direction. The plurality of conductive pillars WP1 and WP2 are disposed in a staggered form on the XY plane. Specifically, the conductive pillars WP1 and WP2 arranged in the same row in the Y direction are disposed successively one by one (alternately). Sets of the conductive pillars WP1 and WP2 alternately arranged in the Y direction are arranged while being shifted by a half pitch in the X direction. Here, the half pitch is, for example, half a distance between the centers of the conductive pillars WP1 and WP2 arranged in the Y direction.

Note that the shapes of the conductive pillars WP1 and WP2 may be different from each other as viewed in the Z direction. Specifically, since the distance from the center does not significantly change between a portion along the memory structure MS and a portion along the insulator INS, the conductive pillar WP1 can have a shape close to that of a perfect circle. In contrast, since the distance from the center significantly changes between a portion along the memory structure MS and a portion along the insulator INS, the conductive pillar WP2 can have a shape collapsed from a perfect circle.

Each of the plurality of insulators INS is an insulator surrounding a portion facing the conductive pillar WP2 adjacent in the Y direction in the outer periphery of the corresponding conductive pillar WP1. For one conductive pillar WP1, the two insulators INS facing two conductive pillars WP2 adjacent to the conductive pillar WP1 in the Y direction are provided apart from each other. The portion of the insulator INS in contact with the channel structure CH is formed concentrically around each of the conductive pillars WP1 and WP2 sandwiching the insulator INS in the Y direction, for example. The portion of the insulator INS formed concentrically around each of the conductive pillars WP1 and WP2 has a convex shape protruding in the X direction toward the channel structure CH. The conductive pillars WP1 and the conductive pillars WP2 are alternately arranged in the Y direction in the same row with the two insulators INS interposed therebetween. As a result, the insulator INS insulates the conductive pillar WP1 from the conductive pillar WP2 adjacent to the conductive pillar WP1 in the Y direction.

Each of the plurality of memory structures MS is a stacked film corresponding to the gate structure of the memory cell transistor MT. Two memory structures MS are disposed for each of the conductive pillars WP1 and WP2. Specifically, the two memory structures MS are provided on the outer periphery of each of the conductive pillar WP1 and WP2 away from each other with the insulator INS interposed therebetween. That is, the two memory structures MS corresponding to the conductive pillar WP1 are arranged in the X direction so as to sandwich the conductive pillar WP1. The two memory structures MS corresponding to the conductive pillar WP2 are arranged in the X direction so as to sandwich the conductive pillar WP1.

Structures in which the conductive pillar WP1 including the two memory structures MS disposed on the outer periphery, the insulator INS, the conductive pillar WP2 including the two memory structures MS disposed on the outer periphery, and the insulator INS are repeatedly arranged in this order in the Y direction (hereinafter, also referred to as “row structures”) are arranged while being shifted by a half pitch in the X direction. In the example of FIG. 29, an example in which the five row structures are arranged in the X direction is illustrated.

Each of the plurality of channel structures CH is a semiconductor extending in the Y direction. The channel structure CH is disposed between the two row structures adjacent in the X direction. Note that the plurality of channel structures CH may be divided from each other at both ends in the Y direction, or may be connected to each other with the select transistors ST1 and ST2 (not illustrated) interposed therebetween.

The memory structure MS and the portions of the conductive pillar WP1 and the channel structure CH sandwiching the memory structure MS function as one memory cell transistor MT. The memory structure MS and the portions of the conductive pillar WP2 and the channel structure CH sandwiching the memory structure MS function as one memory cell transistor MT. The channel structure CH and the portion in contact with the channel structure in the two row structures sandwiching the channel structure CH constitute one NAND string NS. In FIG. 29, four NAND strings NS formed by five row structures arranged in the X direction and four channel structures CH disposed between the five row structures correspond to the string units SU0 to SU3, respectively.

One end of the NAND string NS in the Y direction is connected to the bit line BL with the select transistor ST1 (not illustrated) interposed therebetween. The other end of the NAND string NS in the Y direction is connected to the source line SL with the select transistor ST2 (not illustrated) interposed therebetween.

Each of the plurality of word lines WL extends in the X direction. The plurality of word lines WL are arranged in the Y direction. The word line WL is disposed at a position overlapping the plurality of conductive pillars WP1 and WP2 arranged in the X direction as viewed in the Z direction. The conductive pillars WP1 and WP2 are connected to the corresponding word line WL via the contacts V1 and V2.

### <Cross-Sectional Structure>

Next, the cross-sectional structure of the memory cell array according to the second embodiment will be described.

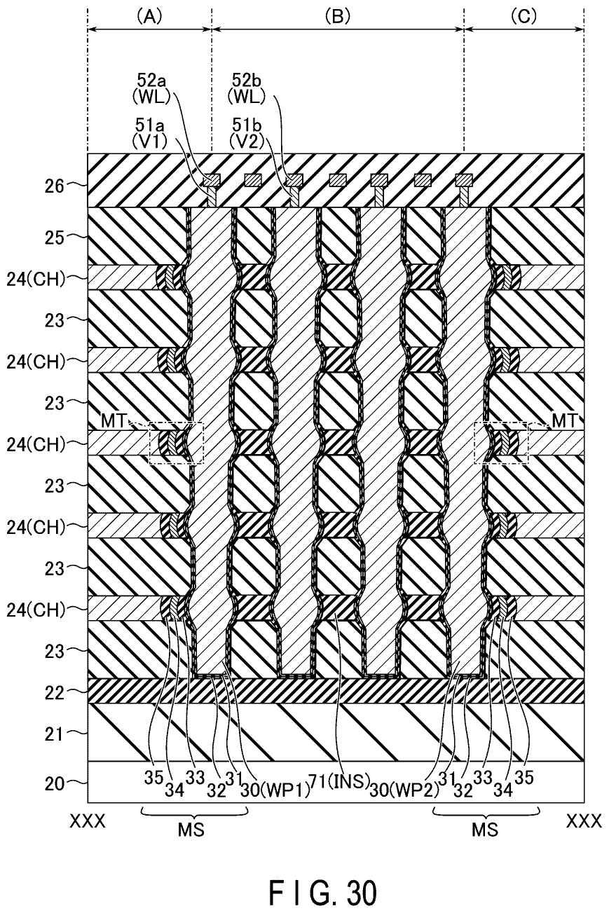

FIG. 30 is a cross-sectional view taken along line XXX-XXX of FIG. 29, illustrating an example of the cross-sectional structure of the memory cell array according to the second embodiment. FIG. 30 corresponds to FIG. 4 in the first embodiment.

As illustrated in FIG. 30, the memory cell array 10 includes a substrate 20, insulating layers 21, 22, 23, 25, and 26, a semiconductor layer 24, a conductor film 30, insulator films 31, 32, 33, 35, and 71, a charge storage film 34, and conductive layers 51a, 51b, 52a, and 52b.

A stacked structure including the substrate 20, the insulating layers 21, 22, 23, 25, and 26, and the semiconductor layer 24 is the same as that of the first embodiment.

The conductor film 30 is a conductor extending in the Z direction so as to cross the plurality of semiconductor layers 24, and functions as the conductive pillar WP1 or WP2. The lower end of the conductor film 30 is located below the semiconductor layer 24 as a lowermost layer and above the insulating layer 22. The upper end of the conductor film 30 is aligned with, for example, the upper end of the insulating layer 25. The conductor film 30 contains, for example, titanium nitride.

The memory structure MS including the insulator films 31, 32, 33, and 35 and the charge storage film 34 is the same as that of the first embodiment.

Each of the plurality of insulator films 71 is provided at the same position as that of each of the plurality of semiconductor layers 24 in the Z direction and functions as the insulator INS. The insulator film 71 extends in the XY plane and is provided between the two insulating layers 23 or the insulating layers 23 and 25. Therefore, the length (film thickness) in the Z direction of the insulator film 71 is substantially equal to the film thickness of the semiconductor layer 24, and there is no portion longer than the film thickness of the semiconductor layer 24. The insulator film 71 contains, for example, silicon oxide.

On the upper surface of the conductor film 30 functioning as the conductive pillar WP1, the conductive layer 51a functioning as the contact V1 is provided. On the upper surface of the conductive layer 51a, the conductive layer 52a functioning as the word line WL is provided. The conductive layer 52a contains, for example, copper.

On the upper surface of the conductor film 30 functioning as the conductive pillar WP2, the conductive layer 51a functioning as the contact V2 is provided. On the upper surface of the conductive layer 51a, the conductive layer 52a functioning as the word line WL is provided. The conductive layer 52a contains, for example, copper.

### 2.2 Producing Method

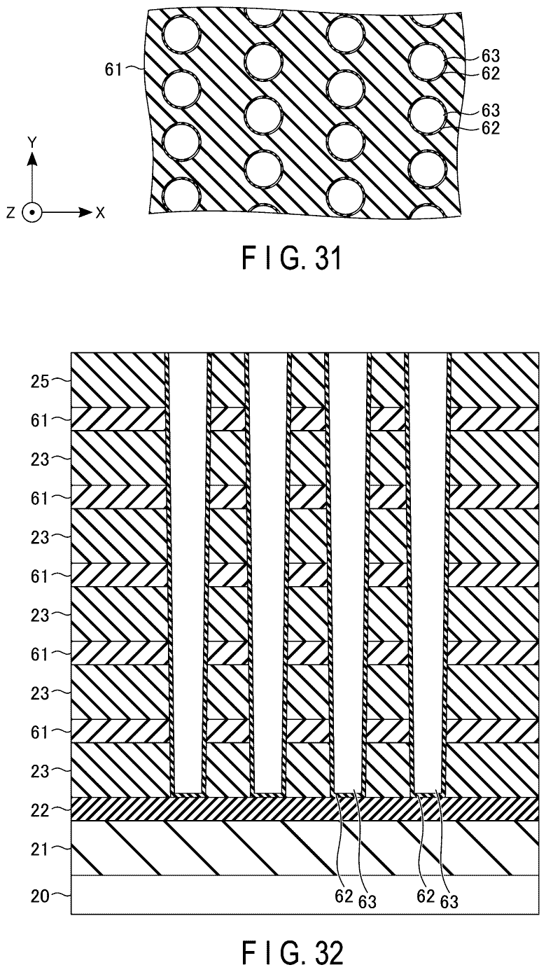

FIGS. 31, 33, 35, 37, 39, 41, 43, 45, and 47 are plan views illustrating an example of the planar layout of the memory device according to the second embodiment under production. FIGS. 32, 34, 36, 38, 40, 42, 44, 46, and 47 are cross-sectional views illustrating an example of the cross-sectional structure of the memory device according to the second embodiment under production. Each of the cross-sectional views illustrated in FIGS. 32, 34, 36, 38, 40, 42, 44, 46, and 47 corresponds to a cross section cut at the same position as that of line XXX-XXX illustrated in FIG. 29 in the planar layout illustrated in FIGS. 31, 33, 35, 37, 39, 41, 43, 45, and 47.

First, a stacked structure is formed on the upper surface of the substrate 20. A process of forming the stacked structure is the same as that in FIGS. 3 and 4 in the first embodiment.

Next, as illustrated in FIGS. 31 and 32, a plurality of holes are provided in a region where the plurality of conductive pillars WP1 and WP2 are to be provided in the stacked structure. The plurality of holes are provided so as to be disposed in a staggered form as viewed in the Z direction. Each of the plurality of holes penetrates the insulating layer 25, a plurality of sacrificial members 61, and the plurality of insulating layers 23. The bottom of each of the plurality of holes reaches the insulating layer 22. A thin insulator film 62 is formed inside each of the plurality of holes. Thereafter, each of the plurality of holes is embedded by a sacrificial member 63.

Here, the plurality of holes are formed so as not to interfere with each other at any position in the Z direction. Therefore, at the position where the insulating layer 23, the sacrificial member 61, and the insulating layer 25 are provided in the Z direction, the insulating layer 23, the sacrificial member 61, and the insulating layer 25 exist between the plurality of holes arranged in the Y direction, respectively.

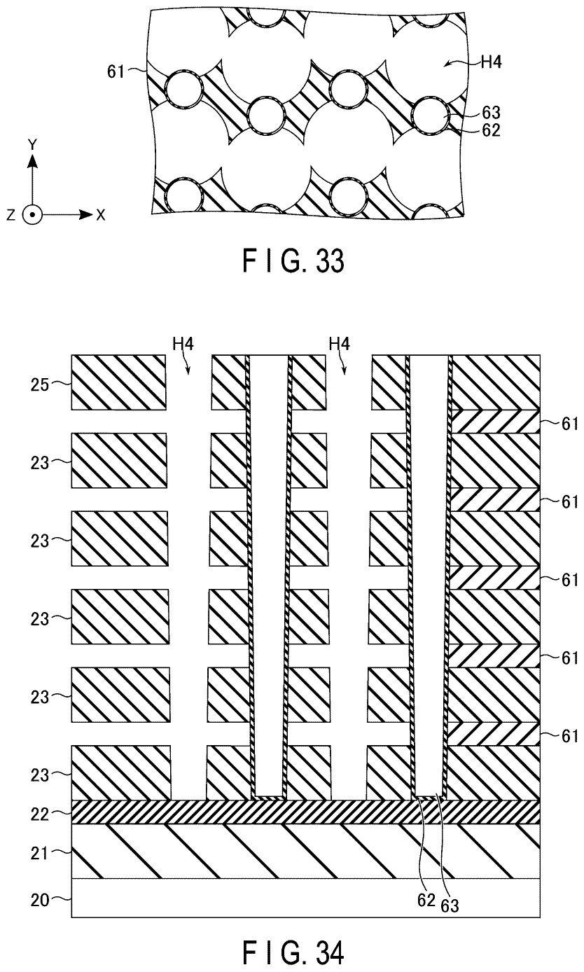

Next, as illustrated in FIGS. 33 and 34, the sacrificial member 63 and the insulator film 62 provided in the region corresponding to the conductive pillar WP1 are removed to form a plurality of holes H4. As a result, the plurality of sacrificial members 61 stacked apart from each other are exposed inside the plurality of holes H4. Thereafter, the sacrificial member 61 is partially removed from the plurality of holes H4. As a result, a groove extending concentrically from the centers of the plurality of holes H4 is formed for each layer provided with the sacrificial member 61. Each of the plurality of grooves formed in the hole H4 is formed with a depth that reaches the insulator film 62 adjacent to the hole H4 in the Y direction. Each of the plurality of grooves formed in the hole H4 is formed with a depth that reaches another hole H4 adjacent to the hole H4 in the X direction. Therefore, the insulator film 62 adjacent to the hole H4 in the Y direction is exposed inside each of the plurality of grooves formed in the hole H4. The hole H4 is connected to another hole H4 adjacent to the hole H4 in the X direction via a plurality of grooves.

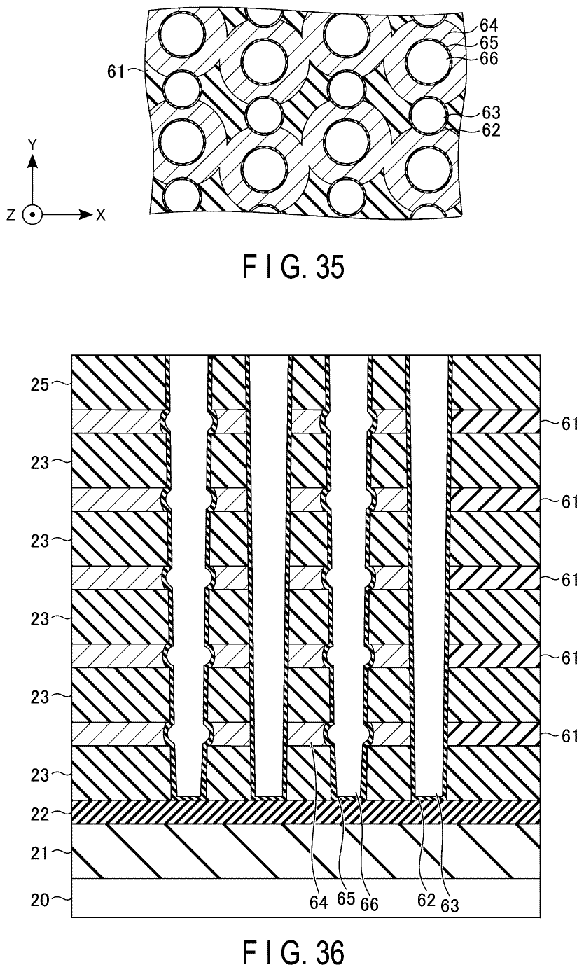

Next, as illustrated in FIGS. 35 and 36, the plurality of holes H4 are embedded by a sacrificial member 64, an insulator film 65, and a sacrificial member 66. Specifically, the plurality of grooves formed in each of the plurality of holes H4 are embedded by the sacrificial member 64. The thin insulator film 65 is formed inside each of the plurality of holes H4. Thereafter, each of the plurality of holes H4 is embedded by the sacrificial member 66.

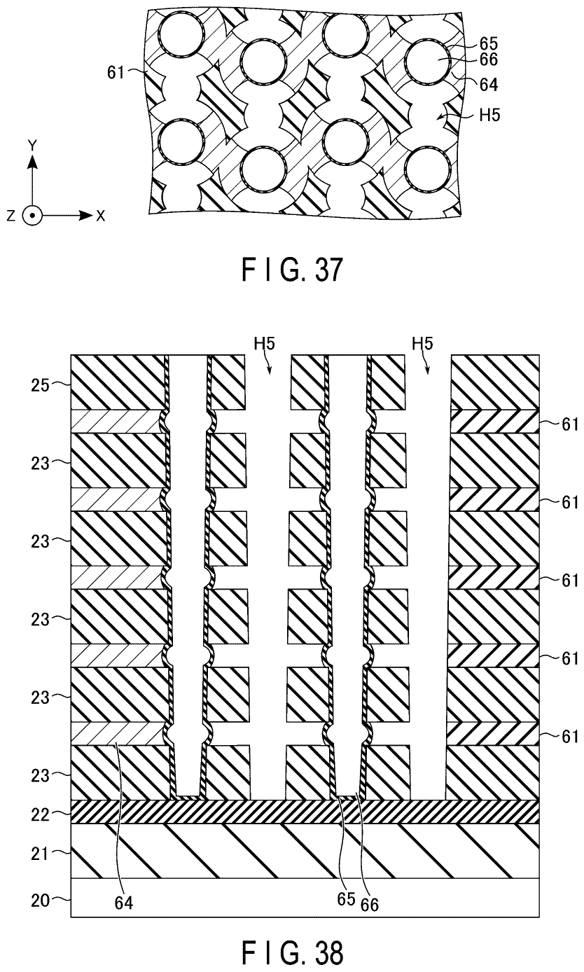

Next, as illustrated in FIGS. 37 and 38, the sacrificial member 63 and the insulator film 62 provided in the region corresponding to the conductive pillar WP2 are removed to form a plurality of holes H5. As a result, the plurality of sacrificial members 64 provided in the same layer as that of the plurality of sacrificial members 61 are exposed inside the plurality of holes H5. Thereafter, the sacrificial member 64 is partially removed from the plurality of holes H5. As a result, a groove extending concentrically from the centers of the plurality of holes H5 is formed for each layer provided with the sacrificial member 64. Each of the plurality of grooves formed in the hole H5 is formed, for example, at the same depth as that of the groove (embedded by the sacrificial member 64) formed in the hole H4. Therefore, the insulator film 65 adjacent to the hole H5 in the Y direction is exposed inside each of the plurality of grooves formed in the hole H5. Each of the plurality of grooves formed in the hole H5 has a contour including a portion along a concentric circle centered on the hole H5 and a portion along a concentric circle centered on the hole H4 as viewed in the Z direction.

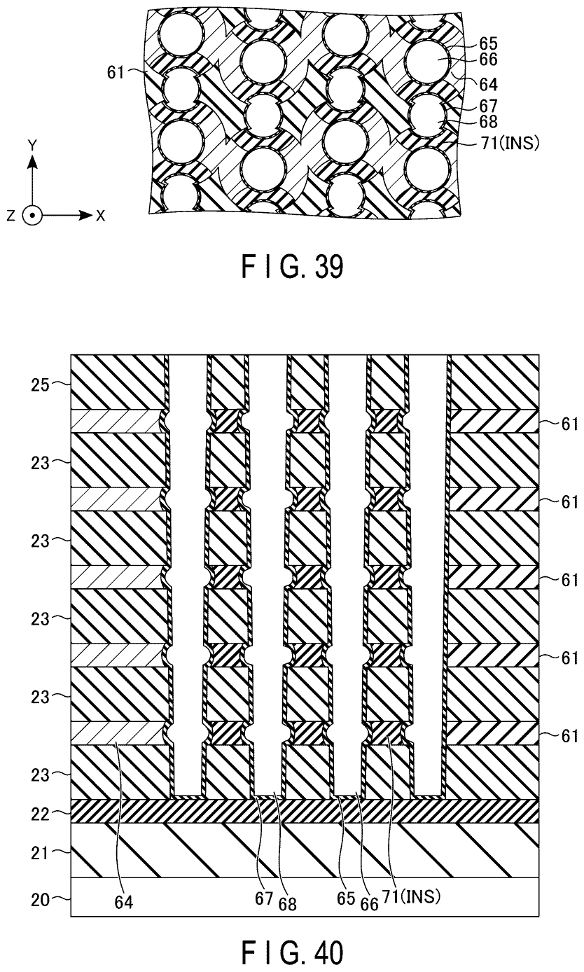

Next, as illustrated in FIGS. 39 and 40, the plurality of holes H5 are embedded by an insulator film 71, an insulator film 67, and a sacrificial member 68. Specifically, the plurality of grooves formed in each of the plurality of holes H5 are embedded by the insulator film 71. Therefore, the insulator film 71 has a shape having a portion along a concentric circle centered on the hole H5 and a portion along a concentric circle centered on the hole H4 as viewed in the Z direction. The thin insulator film 67 is formed inside each of the plurality of holes H5. Thereafter, each of the plurality of holes H5 is embedded by the sacrificial member 68. The insulator film 67 contains, for example, silicon oxide. The sacrificial member 68 contains, for example, polysilicon.

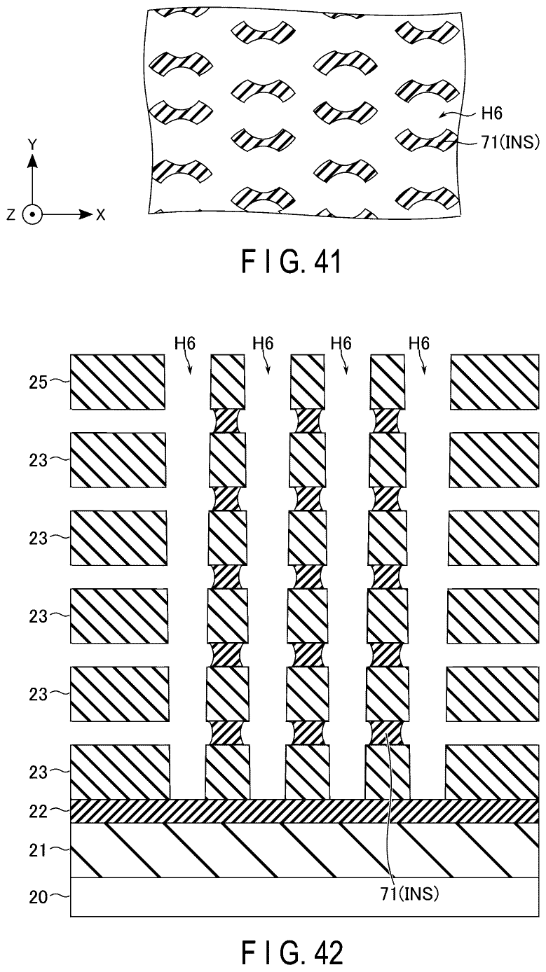

Next, as illustrated in FIGS. 41 and 42, the sacrificial member 66 and the insulator film 65 provided in the region corresponding to the conductive pillar WP1, and the sacrificial member 68 and the insulator film 67 provided in the region corresponding to the conductive pillar WP2 are removed to form a plurality of holes H6. The plurality of sacrificial members 64 stacked apart from each other are exposed inside the hole H6 corresponding to the conductive pillar WP1. The plurality of sacrificial members 61 stacked apart from each other are exposed inside the hole H6 corresponding to the conductive pillar WP2.

Subsequently, the plurality of sacrificial members 64 are removed from the hole H6 corresponding to the conductive pillar WP1. As a result, the plurality of sacrificial members 61 stacked apart from each other are exposed inside the hole H6 corresponding to the conductive pillar WP1. Thereafter, the plurality of sacrificial members 61 are removed from the plurality of holes H6. As a result, the plurality of holes H6 are connected in one via the plurality of grooves.

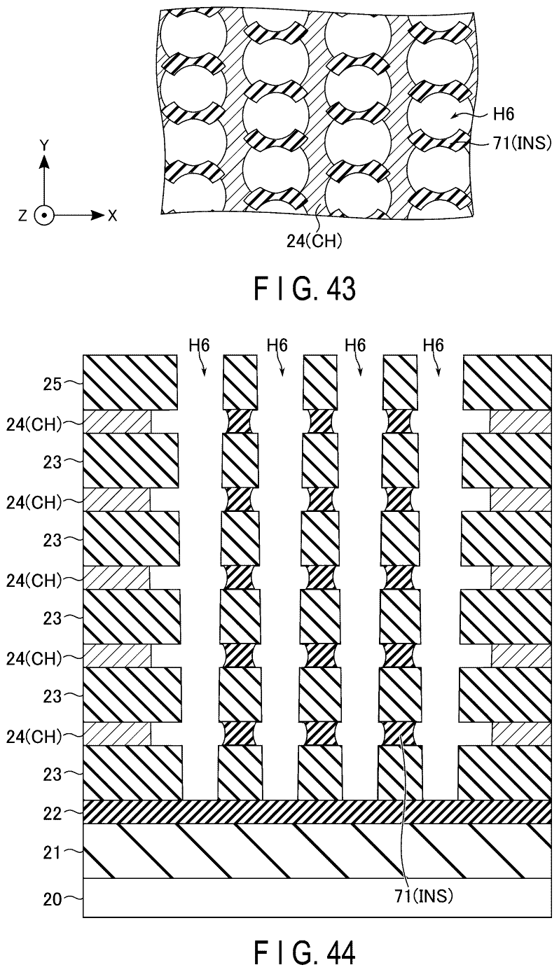

Next, as illustrated in FIGS. 43 and 44, the semiconductor layer 24 is formed via the plurality of holes H6 connected in one via the plurality of grooves. As a result, a region where the channel structure CH is to be formed in the plurality of grooves formed in each of the plurality of holes H6 is embedded by the semiconductor layer 24. The plurality of holes H6 are divided again by the semiconductor layer 24.

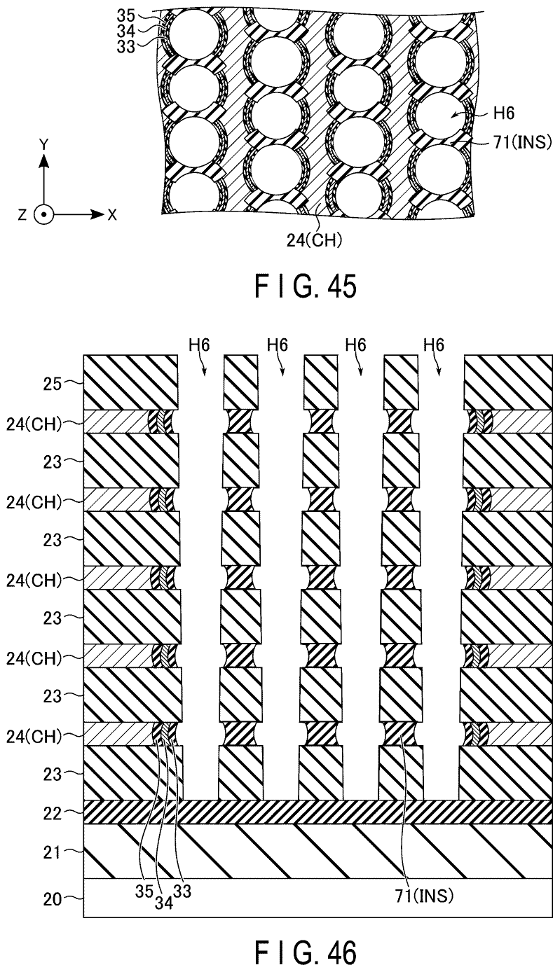

Next, as illustrated in FIGS. 44 and 45, the insulator film 35, the charge storage film 34, and the insulator film 33 are formed via the plurality of holes H6. As a result, each of the plurality of grooves formed in each of the plurality of holes H6 is embedded by the stacked film of the insulator film 35, the charge storage film 34, and the insulator film 33.

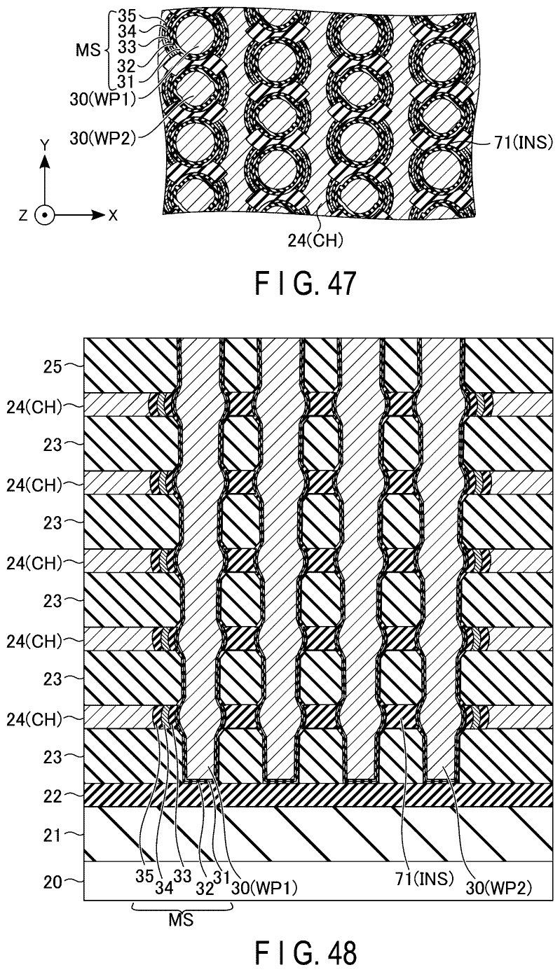

Next, as illustrated in FIGS. 46 and 47, the insulator film 32, the insulator film 31, and the conductor film 30 are formed via the plurality of holes H6 to embed the plurality of holes H6.

Thereafter, a structure above the stacked structure of the memory cell array 10 is formed. Thus, a memory device 3 is formed.

### 2.3 Effects According to Second Embodiment

According to the second embodiment, the region where the plurality of holes corresponding to the conductive pillars WP1 and WP2 are formed has a stacked structure of the insulating layer 23 and the sacrificial member 61. As a result, for example, in the region where the plurality of holes corresponding to the conductive pillars WP1 and WP2 are formed, the processing becomes easier than in a case where the region where the stacked structure of the silicon oxide layer and the silicon nitride layer is processed and the region where the stacked structure including only the silicon oxide layer is processed are mixed. Therefore, an increase in the producing cost of the memory device 3 can be suppressed.

The plurality of holes corresponding to the conductive pillars WP1 and WP2 are collectively formed. As a result, the step of processing the stacked structure of the insulating layer 23 and the sacrificial member 61 in the Z direction can be performed once. Therefore, an increase in the producing cost of the memory device 3 can be suppressed.

In a case where a plurality of holes corresponding to the conductive pillars WP1 and WP2 are formed, all the holes correspond to any of the conductive pillars WP1 and WP2. As a result, the integration density of the memory cell transistors MT can be increased as compared with the case where a part of the collectively formed holes is used as the conductive pillars WP1 and WP2.

### 3. THIRD EMBODIMENT

Next, a memory device according to a third embodiment will be described. The memory device according to the third embodiment is different from the second embodiment in that the shape of the memory structure MS is significantly different between the conductive pillars WP1 and WP2.

Hereinafter, a configuration and a producing method different from those of the second embodiment will be mainly described. The descriptions of the same configuration and producing method as those of the second embodiment will be appropriately omitted.

### 3.1 Configuration

### <Circuit Configuration>

First, the circuit configuration of a memory cell array according to the third embodiment will be described.

The circuit configuration of a memory cell array 10 in the third embodiment is the same as the circuit configuration of the memory cell array 10 in the second embodiment. That is, a NAND string NS included in the memory cell array 10 includes a plurality of memory cell transistors MT0 to MT7 connected in series, and select transistors ST1 and ST2 provided at both ends of the plurality of memory cell transistors MT, respectively.

### <Planar Layout>

Next, the planar layout of the memory cell array according to the third embodiment will be described.

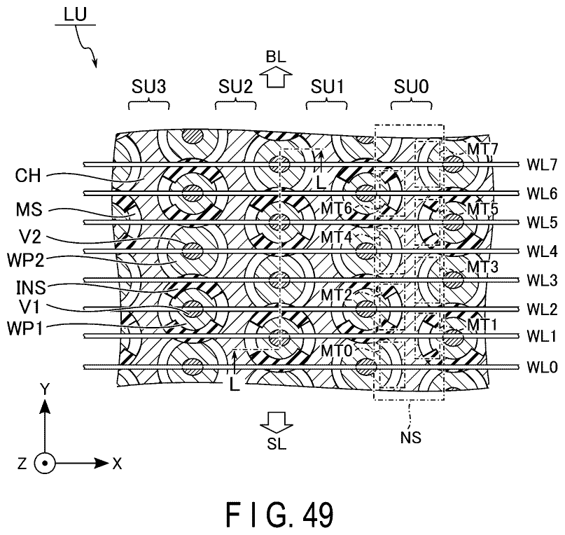

FIG. 49 is a plan view illustrating an example of the planar layout of the memory cell array according to the third embodiment. FIG. 49 corresponds to FIG. 29 in the second embodiment.

As illustrated in FIG. 49, in the same layer, the memory cell array 10 includes a plurality of conductive pillars WP1 and WP2, a plurality of memory structures MS, a plurality of insulators INS, a channel structure CH, a plurality of word lines WL, and a plurality of contacts V1 and V2.

Each of the plurality of conductive pillars WP1 and WP2 is a conductor having a columnar shape extending in the Z direction. The plurality of conductive pillars WP1 and WP2 are disposed in a staggered form on the XY plane. Specifically, the conductive pillars WP1 and WP2 arranged in the same row in the Y direction are disposed successively one by one (alternately). Sets of the conductive pillars WP1 and WP2 alternately arranged in the Y direction are arranged while being shifted by a half pitch in the X direction. Here, the half pitch is, for example, half a distance between the centers of the conductive pillars WP1 and WP2 arranged in the Y direction.

Each of the plurality of insulators INS is an insulator surrounding a portion facing the conductive pillar WP2 adjacent in the Y direction in the outer periphery of the corresponding conductive pillar WP1. The two insulators INS are provided separately from one conductive pillar WP1 in the Y direction. The portion of the insulator INS in contact with the channel structure CH is formed concentrically around the conductive pillar WP1, for example. The conductive pillars WP1 and the conductive pillars WP2 are alternately arranged in the Y direction in the same row with the two insulators INS interposed therebetween. As a result, the insulator INS insulates the conductive pillar WP1 from the conductive pillar WP2 adjacent to the conductive pillar WP1 in the Y direction.

Each of the plurality of memory structures MS is a stacked film corresponding to the gate structure of the memory cell transistor MT. The two memory structures MS are disposed for each of the conductive pillars WP1 and WP2. Specifically, the two memory structures MS are provided on the outer periphery of each of the conductive pillar WP1 and WP2 away from each other with the insulator INS interposed therebetween. That is, the two memory structures MS corresponding to the conductive pillar WP1 are arranged in the X direction so as to sandwich the conductive pillar WP1. The two memory structures MS corresponding to the conductive pillar WP2 are arranged in the X direction so as to sandwich the conductive pillar WP1. The two memory structures MS corresponding to the conductive pillar WP1 and the two memory structures MS corresponding to the conductive pillar WP2 may have different shapes as viewed in the Z direction. Specifically, the two memory structures MS corresponding to the conductive pillar WP1 are shorter than the two memory structures MS corresponding to the conductive pillar WP2.

Structures in which the conductive pillar WP1 including the two memory structures MS disposed on the outer periphery, the insulator INS, the conductive pillar WP2 including the two memory structures MS disposed on the outer periphery, and the insulator INS are repeatedly arranged in this order in the Y direction (hereinafter, also referred to as “row structures”) are arranged while being shifted by a half pitch in the X direction. In the example of FIG. 49, an example in which the five row structures are arranged in the X direction is illustrated.

Each of the plurality of channel structures CH is a semiconductor extending in the Y direction. The channel structure CH is disposed between the two row structures adjacent in the X direction. Note that the plurality of channel structures CH may be divided from each other at both ends in the Y direction, or may be connected to each other with the select transistors ST1 and ST2 (not illustrated) interposed therebetween.

The memory structure MS and the portions of the conductive pillar WP1 and the channel structure CH sandwiching the memory structure MS function as one memory cell transistor MT. The memory structure MS and the portions of the conductive pillar WP2 and the channel structure CH sandwiching the memory structure MS function as one memory cell transistor MT. The channel structure CH and the portion in contact with the channel structure in the two row structures sandwiching the channel structure CH constitute one NAND string NS. In FIG. 49, four NAND strings NS formed by five row structures arranged in the X direction and four channel structures CH disposed between the five row structures correspond to the string units SU0 to SU3, respectively.

One end of the NAND string NS in the Y direction is connected to the bit line BL with the select transistor ST1 (not illustrated) interposed therebetween. The other end of the NAND string NS in the Y direction is connected to the source line SL with the select transistor ST2 (not illustrated) interposed therebetween.

Each of the plurality of word lines WL extends in the X direction. The plurality of word lines WL are arranged in the Y direction. The word line WL is disposed at a position overlapping the plurality of conductive pillars WP1 and WP2 arranged in the X direction as viewed in the Z direction. The conductive pillars WP1 and WP2 are connected to the corresponding word line WL via the contacts V1 and V2.

### <Cross-Sectional Structure>

Next, the cross-sectional structure of the memory cell array according to the third embodiment will be described.

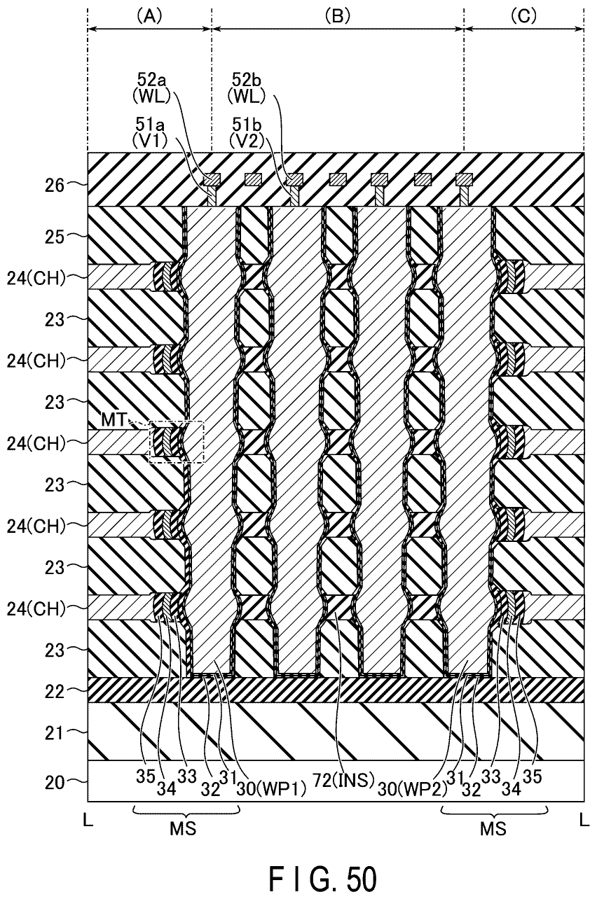

FIG. 50 is a cross-sectional view taken along line L-L of FIG. 49, illustrating an example of the cross-sectional structure of the memory cell array according to the third embodiment. FIG. 50 corresponds to FIG. 30 in the second embodiment.

As illustrated in FIG. 50, the memory cell array 10 includes a substrate 20, insulating layers 21, 22, 23, 25, and 26, a semiconductor layer 24, a conductor film 30, insulator films 31, 32, 33, 35, and 72, a charge storage film 34, and conductive layers 51a, 51b, 52a, and 52b.

A stacked structure including the substrate 20, the insulating layers 21, 22, 23, 25, and 26, and the semiconductor layer 24 is the same as that of the second embodiment.

The conductor film 30 is a conductor extending in the Z direction so as to cross the plurality of semiconductor layers 24, and functions as the conductive pillar WP1 or WP2. The lower end of the conductor film 30 is located below the semiconductor layer 24 as a lowermost layer and above the insulating layer 22. The upper end of the conductor film 30 is aligned with, for example, the upper end of the insulating layer 25. The conductor film 30 contains, for example, titanium nitride.

The memory structure MS including the insulator films 31, 32, 33, and 35 and the charge storage film 34 is the same as that of the second embodiment.

Each of a plurality of insulator films 72 is provided at the same position as that of each of the plurality of semiconductor layers 24 in the Z direction and functions as the insulator INS. The insulator film 72 extends in the XY plane and is provided between the two insulating layers 23 or the insulating layers 23 and 25. Therefore, the length (film thickness) in the Z direction of the insulator film 72 is substantially equal to the film thickness of the semiconductor layer 24, and there is no portion longer than the film thickness of the semiconductor layer 24. The insulator film 72 contains, for example, silicon oxide.

The structures of the conductive layers 51a and 51b and the conductive layers 52a and 52b are the same as those of the second embodiment.

### 3.2 Producing Method

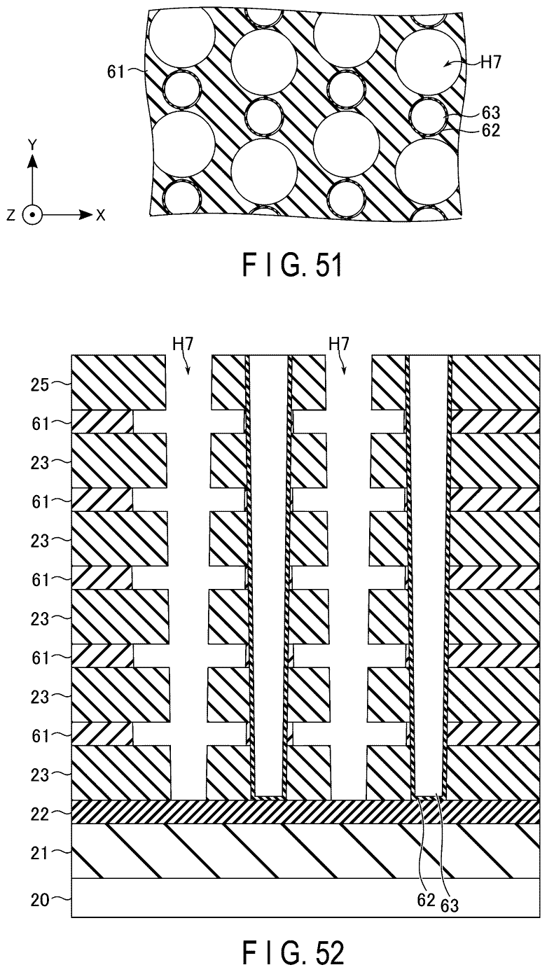

FIGS. 51, 53, 55, 57, 59, 61, 63, 65, 67, 69, and 71 are plan views illustrating an example of the planar layout of the memory device according to the third embodiment under production. FIGS. 52, 54, 56, 58, 60, 62, 64, 66, 68, 70, and 72 are cross-sectional views illustrating an example of the cross-sectional structure of the memory device according to the third embodiment under production. Each of the cross-sectional views illustrated in FIGS. 52, 54, 56, 58, 60, 62, 64, 66, 68, 70, and 72 corresponds to a cross section cut at the same position as that of line L-L illustrated in FIG. 49 in the planar layout illustrated in FIGS. 51, 53, 55, 57, 59, 61, 63, 65, 67, 69, and 71.

First, the same structure as that in FIGS. 31 and 32 in the second embodiment is formed by the same step as that in the second embodiment.

Next, as illustrated in FIGS. 51 and 52, a sacrificial member 63 and an insulator film 62 provided in the region corresponding to the conductive pillar WP1 are removed to form a plurality of holes H7. As a result, a plurality of sacrificial members 61 stacked apart from each other are exposed inside the plurality of holes H7. Thereafter, the sacrificial member 61 is partially removed from the plurality of holes H7. As a result, a groove extending concentrically from the centers of the plurality of holes H7 is formed for each layer provided with the sacrificial member 61. Each of the plurality of grooves formed in the hole H7 is formed with a depth that does not reach the insulator film 62 adjacent to the hole H7 in the Y direction. In other words, the insulator film 62 is not exposed inside the groove formed in the hole H7.

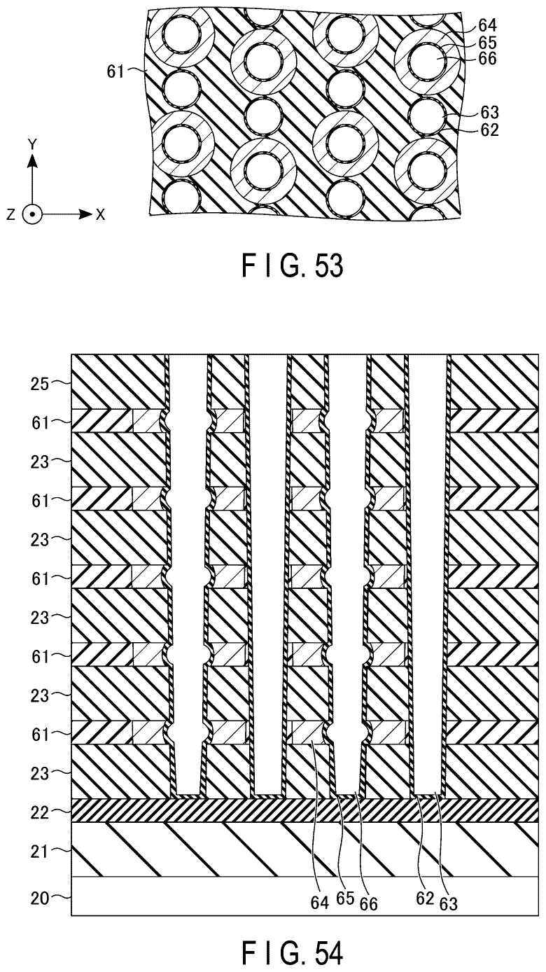

Next, as illustrated in FIGS. 53 and 54, the plurality of holes H7 are embedded by a sacrificial member 64, an insulator film 65, and a sacrificial member 66.

Specifically, the plurality of grooves formed in each of the plurality of holes H7 are embedded by the sacrificial member 64. The thin insulator film 65 is formed inside each of the plurality of holes H7. Thereafter, each of the plurality of holes H7 is embedded by the sacrificial member 66.

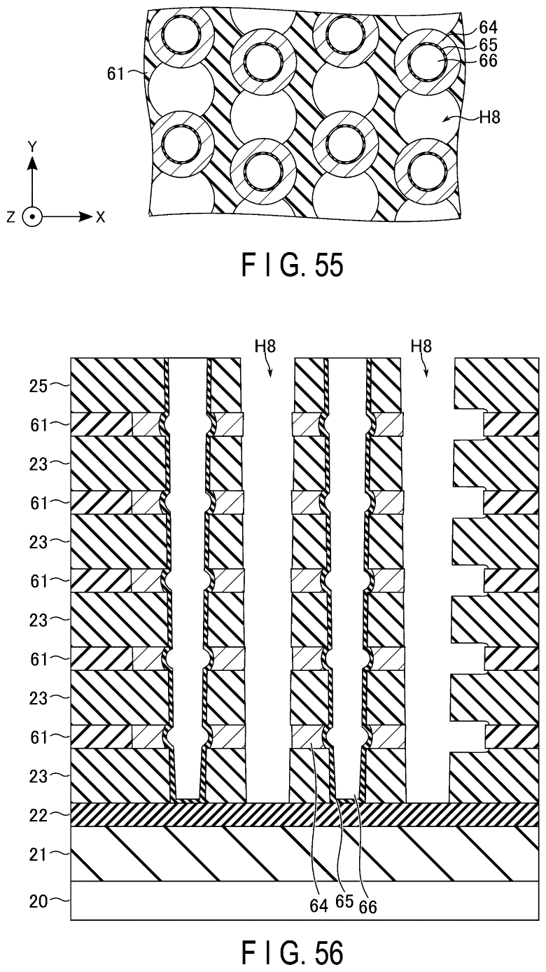

Next, as illustrated in FIGS. 55 and 56, a sacrificial member 63 and the insulator film 62 provided in the region corresponding to the conductive pillar WP2 are removed to form a plurality of holes H8. As a result, the plurality of sacrificial members 61 stacked apart from each other are exposed inside the plurality of holes H8. Thereafter, the sacrificial member 61 is partially removed from the plurality of holes H8. As a result, a groove extending concentrically from the centers of the plurality of holes H8 is formed for each layer provided with the sacrificial member 61. The groove formed in the hole H8 is formed, for example, at the same depth as that of the groove (embedded by the sacrificial member 64) formed in the hole H7. In the groove formed in the hole H8, the sacrificial member 64 adjacent in the Y direction is exposed, but the sacrificial member 64 adjacent in the X direction is not exposed.

Thereafter, the insulating layers 23 and 25 are partially removed from the plurality of holes H8. As a result, the insulating layers 23 and 25 are removed from the groove formed in the hole H8. Therefore, the groove formed in the hole H8 is larger in the Z direction than the film thickness of the sacrificial member 61. In other words, the plurality of insulating layers 23 and 25 are thinned.

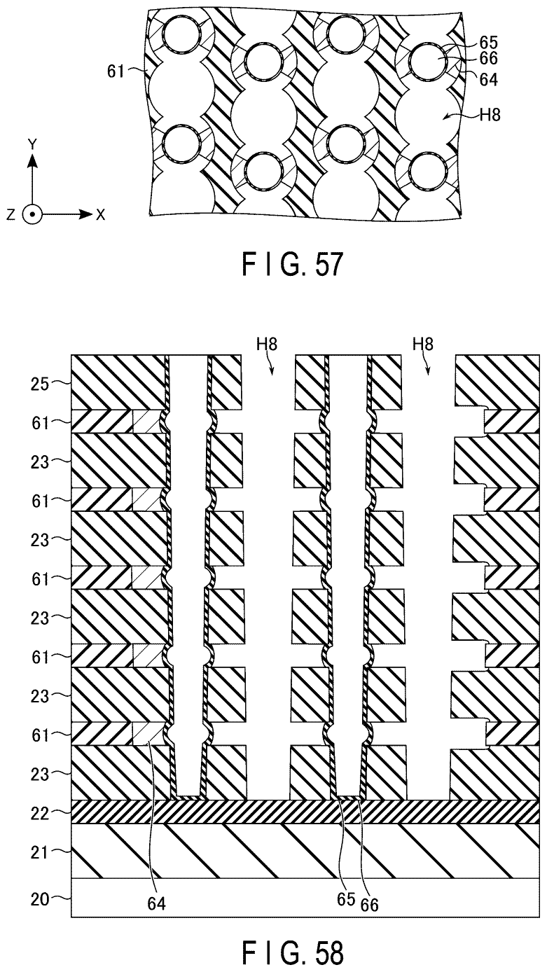

Next, as illustrated in FIGS. 57 and 58, the sacrificial member 64 is partially removed from the plurality of holes H8. As a result, the sacrificial member 64 is divided into two portions sandwiching the sacrificial member 66 in the X direction. That is, the portion of the insulator film 65 facing the hole H8 is exposed inside the hole H8 at the position where the sacrificial member 64 is formed in the Z direction. A region where the sacrificial member 64 divided into two portions remains corresponds to a region where the memory structure MS is to be provided.

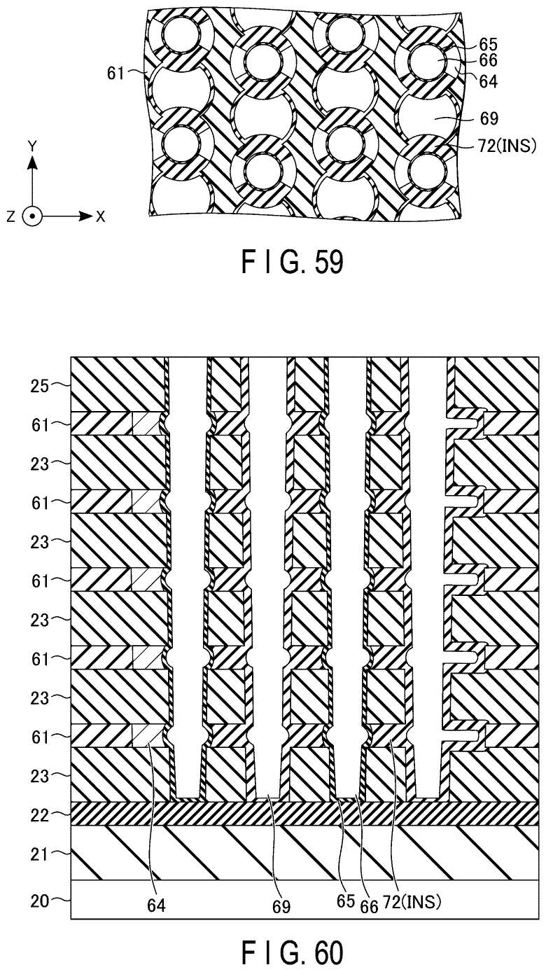

Next, as illustrated in FIGS. 59 and 60, the plurality of holes H8 are embedded by an insulator film 72 and a sacrificial member 69. Specifically, the groove formed by removing the sacrificial member 64 is embedded by the insulator film 72. Thereafter, the plurality of holes H8 are embedded by the sacrificial member 69. The sacrificial member 69 contains, for example, polysilicon.

As described above, the groove in the hole H8 formed by removing the sacrificial member 61 is formed is enlarged in the Z direction by removing the insulating layers 23 and 25, and thus is not closed by the insulator film 72. Therefore, the sacrificial member 69 is also formed inside a groove that is not closed after the formation of the insulator film 72.

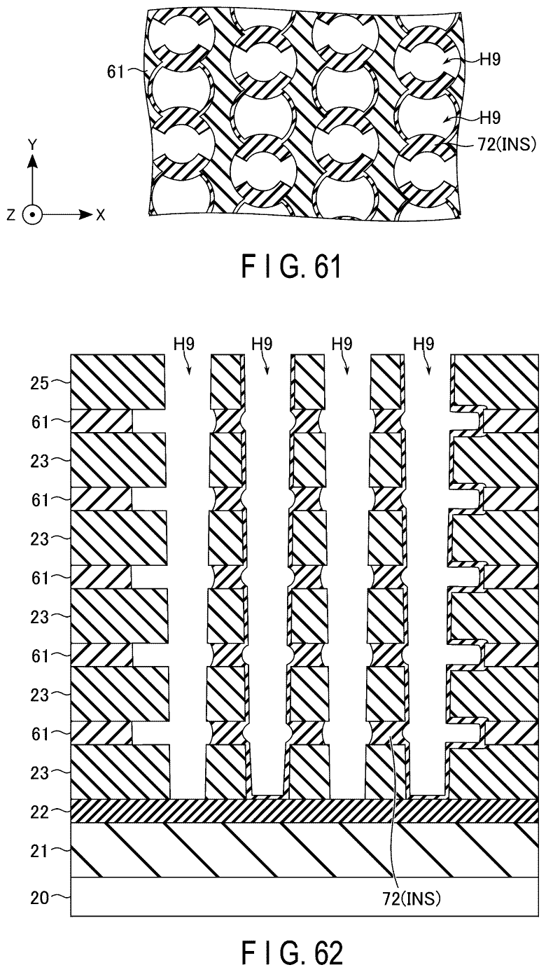

Next, as illustrated in FIGS. 61 and 62, parts of the sacrificial member 66 and the insulator film 65 provided in the region corresponding to the conductive pillar WP1, and the sacrificial member 69 and the insulator film 72 provided in the region corresponding to the conductive pillar WP2 are removed to form a plurality of holes H9. The plurality of sacrificial members 64 stacked apart from each other are exposed inside the hole H9 corresponding to the conductive pillar WP1. Meanwhile, the insulator film 72 formed on the sacrificial member 61 remains in the plurality of grooves formed in the hole H9 corresponding to the conductive pillar WP2.

Subsequently, the plurality of sacrificial members 64 are removed from the hole H9 corresponding to the conductive pillar WP1. As a result, a plurality of grooves are formed in each of the plurality of holes H9 corresponding to the conductive pillar WP1.

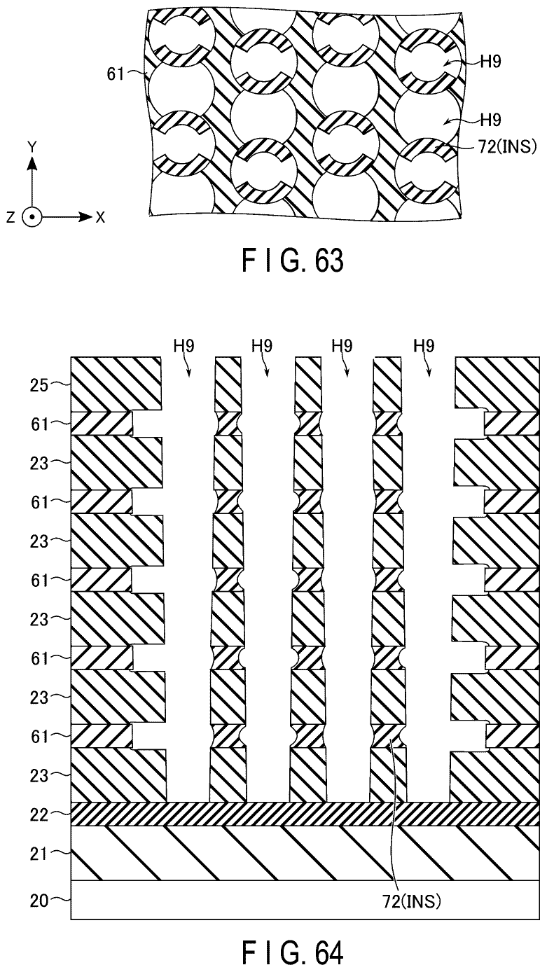

Next, as illustrated in FIGS. 63 and 64, a part of the insulator film 72 is removed from the plurality of holes H9. As a result, the sacrificial member 61 is exposed inside each of the plurality of grooves formed in each of the plurality of holes H9 corresponding to the conductive pillar WP2.

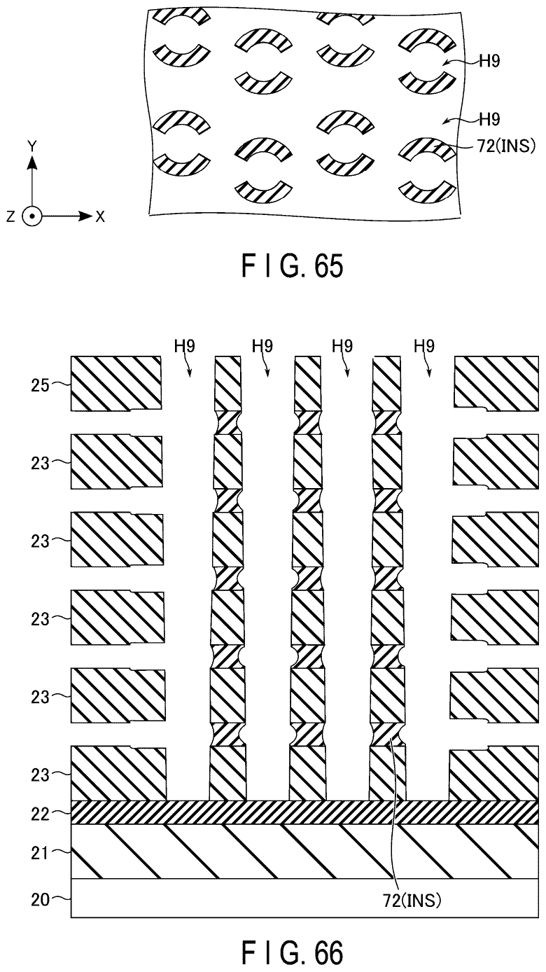

Next, as illustrated in FIGS. 65 and 66, the plurality of sacrificial member 61 are removed from the plurality of holes H9. As a result, the plurality of holes H9 are connected in one via the plurality of grooves.

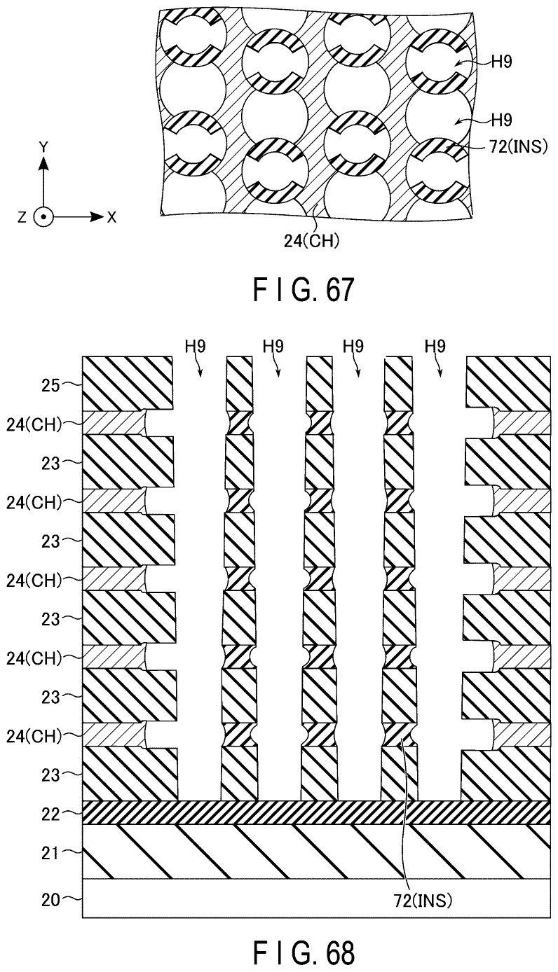

Next, as illustrated in FIGS. 67 and 68, the semiconductor layer 24 is formed via the plurality of holes H9 connected in one via the plurality of grooves. As a result, a region where the channel structure CH is to be formed in the plurality of grooves formed in each of the plurality of holes H9 is embedded by the semiconductor layer 24. The plurality of holes H9 are divided again by the semiconductor layer 24.

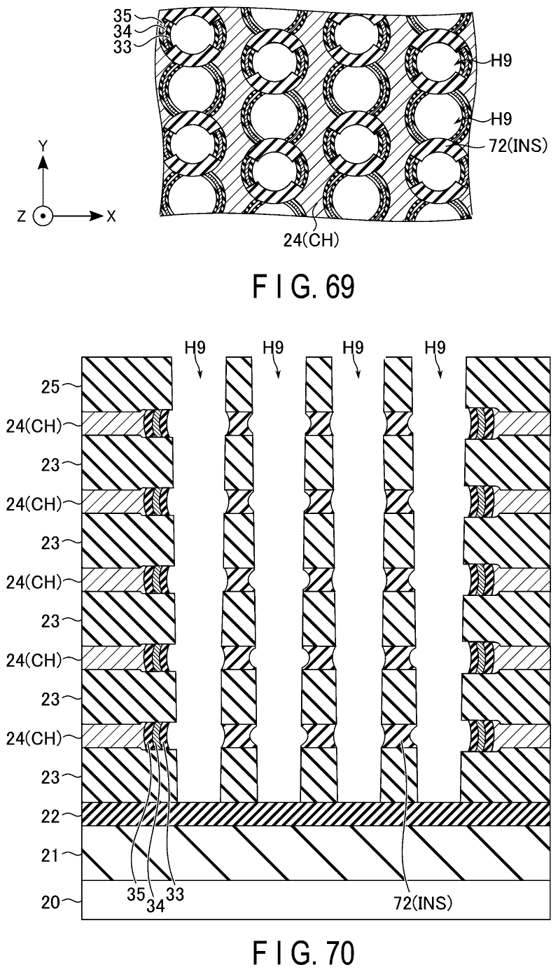

Next, as illustrated in FIGS. 69 and 70, the insulator film 35, the charge storage film 34, and the insulator film 33 are formed via the plurality of holes H9. As a result, each of the plurality of grooves formed in each of the plurality of holes H9 is embedded by the stacked film of the insulator film 35, the charge storage film 34, and the insulator film 33.

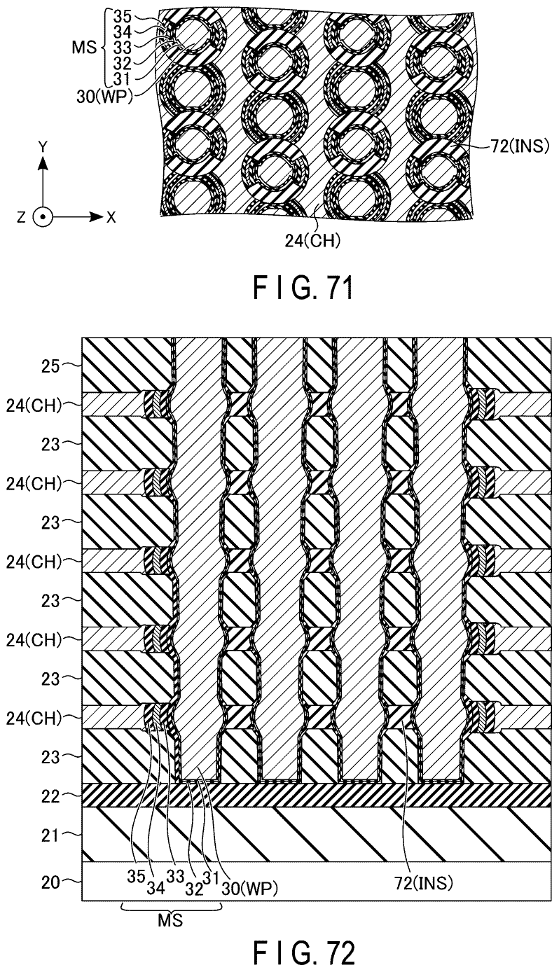

Next, as illustrated in FIGS. 71 and 72, the insulator film 32, the insulator film 31, and the conductor film 30 are formed via the plurality of holes H9 to embed the plurality of holes H9.

Thereafter, a structure above the stacked structure of the memory cell array 10 is formed. Thus, a memory device 3 is formed.

### 3.3 Effects According to Third Embodiment

According to the third embodiment, the region where the plurality of holes corresponding to the conductive pillars WP1 and WP2 are formed has a stacked structure of the insulating layer 23 and the sacrificial member 61. As a result, for example, in the region where the plurality of holes corresponding to the conductive pillars WP1 and WP2 are formed, the processing becomes easier than in a case where the region where the stacked structure of the silicon oxide layer and the silicon nitride layer is processed and the region where the stacked structure including only the silicon oxide layer is processed are mixed. Therefore, an increase in the producing cost of the memory device 3 can be suppressed.

The plurality of holes corresponding to the conductive pillars WP1 and WP2 are collectively formed. As a result, the step of processing the stacked structure of the insulating layer 23 and the sacrificial member 61 in the Z direction can be performed once. Therefore, an increase in the producing cost of the memory device 3 can be suppressed.

In a case where a plurality of holes corresponding to the conductive pillars WP1 and WP2 are formed, all the holes correspond to any of the conductive pillars WP1 and WP2. As a result, the integration density of the memory cell transistors MT can be increased as compared with the case where a part of the collectively formed holes is used as the conductive pillars WP1 and WP2.

### 4. FOURTH EMBODIMENT

Next, a memory device according to a fourth embodiment will be described. The memory device according to the fourth embodiment is different from the third embodiment in that the shape of the memory structure MS is the same in the conductive pillars WP1 and WP2, and the insulator INS has an X-shape. Hereinafter, a configuration and a producing method different from those of the third embodiment will be mainly described. The descriptions of the same configuration and producing method as those of the third embodiment will be appropriately omitted.

### 4.1 Configuration

### <Circuit Configuration>

First, the circuit configuration of a memory cell array according to the fourth embodiment will be described.

The circuit configuration of a memory cell array 10 in the fourth embodiment is the same as the circuit configuration of the memory cell array 10 in the third embodiment. That is, a NAND string NS included in the memory cell array 10 includes a plurality of memory cell transistors MT0 to MT7 connected in series, and select transistors ST1 and ST2 provided at both ends of the plurality of memory cell transistors MT, respectively.

### <Planar Layout>

Next, the planar layout of the memory cell array according to the fourth embodiment will be described.

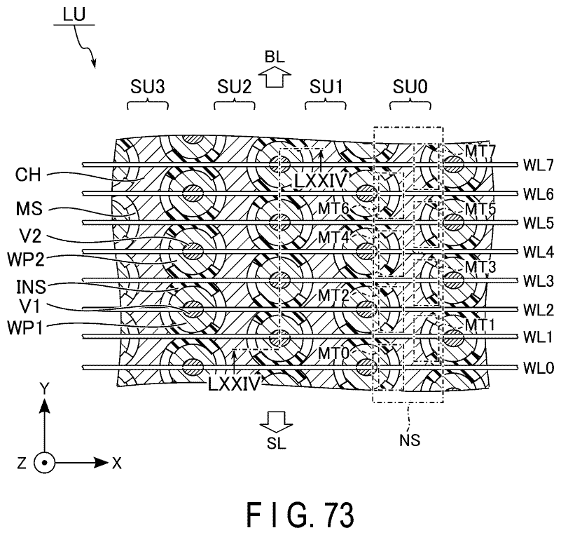

FIG. 73 is a plan view illustrating an example of the planar layout of the memory cell array according to the fourth embodiment. FIG. 73 corresponds to FIG. 49 in the third embodiment.

As illustrated in FIG. 73, in the same layer, the memory cell array 10 includes a plurality of conductive pillars WP1 and WP2, a plurality of memory structures MS, a plurality of insulators INS, a channel structure CH, a plurality of word lines WL, and a plurality of contacts V1 and V2.

Each of the plurality of conductive pillars WP1 and WP2 is a conductor having a columnar shape extending in the Z direction. The plurality of conductive pillars WP1 and WP2 are disposed in a staggered form on the XY plane. Specifically, the conductive pillars WP1 and WP2 arranged in the same row in the Y direction are disposed successively one by one (alternately). Sets of the conductive pillars WP1 and WP2 alternately arranged in the Y direction are arranged while being shifted by a half pitch in the X direction. Here, the half pitch is, for example, half a distance between the centers of the conductive pillars WP1 and WP2 arranged in the Y direction.

The conductive pillars WP1 and WP2 can have the same shape as viewed in the Z direction. Specifically, since the distance from the center does not significantly change between a portion along the memory structure MS and a portion along the insulator INS, both the conductive pillars WP1 and WP2 can have a shape close to that of a perfect circle.

Each of the plurality of insulators INS is an insulator surrounding portions facing each other in the outer periphery of each of the corresponding conductive pillars WP1 and WP2. The two insulators INS are provided separately from one conductive pillar WP1 in the Y direction. The portion of the insulator INS in contact with the channel structure CH has a portion formed concentrically around each of the conductive pillars WP1 and WP2, for example. The portion of the insulator INS formed concentrically around each of the conductive pillars WP1 and WP2 has a concave shape in which the channel structure CH bites into the X direction. The conductive pillars WP1 and the conductive pillars WP2 are alternately arranged in the Y direction in the same row with the two insulators INS interposed therebetween. As a result, the insulator INS insulates the conductive pillar WP1 from the conductive pillar WP2 adjacent to the conductive pillar WP1 in the Y direction.

Each of the plurality of memory structures MS is a stacked film corresponding to the gate structure of the memory cell transistor MT. The two memory structures MS are disposed for each of the conductive pillars WP1 and WP2. Specifically, the two memory structures MS are provided on the outer periphery of each of the conductive pillar WP1 and WP2 away from each other with the insulator INS interposed therebetween. That is, the two memory structures MS corresponding to the conductive pillar WP1 are arranged in the X direction so as to sandwich the conductive pillar WP1. The two memory structures MS corresponding to the conductive pillar WP2 are arranged in the X direction so as to sandwich the conductive pillar WP1.

Structures in which the conductive pillar WP1 including the two memory structures MS disposed on the outer periphery, the insulator INS, the conductive pillar WP2 including the two memory structures MS disposed on the outer periphery, and the insulator INS are repeatedly arranged in this order in the Y direction (hereinafter, also referred to as “row structures”) are arranged while being shifted by a half pitch in the X direction. In the example of FIG. 73, an example in which the five row structures are arranged in the X direction is illustrated.

Each of the plurality of channel structures CH is a semiconductor extending in the Y direction. The channel structure CH is disposed between the two row structures adjacent in the X direction. Note that the plurality of channel structures CH may be divided from each other at both ends in the Y direction, or may be connected to each other with the select transistors ST1 and ST2 (not illustrated) interposed therebetween.

The memory structure MS and the portions of the conductive pillar WP1 and the channel structure CH sandwiching the memory structure MS function as one memory cell transistor MT. The memory structure MS and the portions of the conductive pillar WP2 and the channel structure CH sandwiching the memory structure MS function as one memory cell transistor MT. The channel structure CH and the portion in contact with the channel structure in the two row structures sandwiching the channel structure CH constitute one NAND string NS. In FIG. 73, four NAND strings NS formed by five row structures arranged in the X direction and four channel structures CH disposed between the five row structures correspond to the string units SU0 to SU3, respectively.

One end of the NAND string NS in the Y direction is connected to the bit line BL with the select transistor ST1 (not illustrated) interposed therebetween. The other end of the NAND string NS in the Y direction is connected to the source line SL with the select transistor ST2 (not illustrated) interposed therebetween.

Each of the plurality of word lines WL extends in the X direction. The plurality of word lines WL are arranged in the Y direction. The word line WL is disposed at a position overlapping the plurality of conductive pillars WP1 and WP2 arranged in the X direction as viewed in the Z direction. The conductive pillars WP1 and WP2 are connected to the corresponding word line WL via the contacts V1 and V2.

### <Cross-Sectional Structure>

Next, the cross-sectional structure of the memory cell array according to the fourth embodiment will be described.

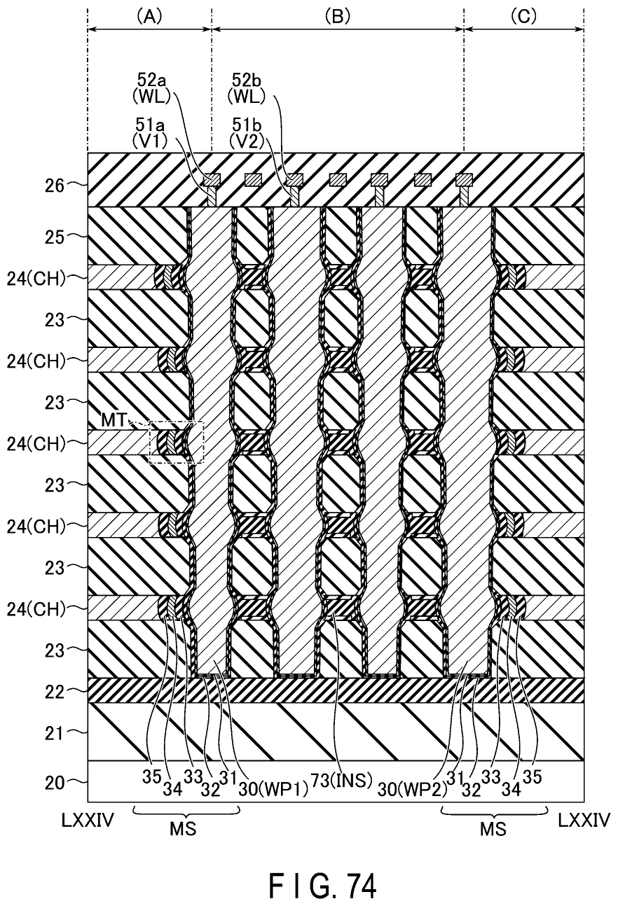

FIG. 74 is a cross-sectional view taken along line LXXIV-LXXIV of FIG. 73, illustrating an example of the cross-sectional structure of the memory cell array according to the fourth embodiment. FIG. 74 corresponds to FIG. 50 in the third embodiment.

As illustrated in FIG. 74, the memory cell array 10 includes a substrate 20, insulating layers 21, 22, 23, 25, and 26, a semiconductor layer 24, a conductor film 30, insulator films 31, 32, 33, 35, and 73, a charge storage film 34, and conductive layers 51a, 51b, 52a, and 52b.

A stacked structure including the substrate 20, the insulator layers 21, 22, 23, 25, and 26, and the semiconductor layer 24 is the same as that of the third embodiment.

The conductor film 30 is a conductor extending in the Z direction so as to cross the plurality of semiconductor layers 24, and functions as the conductive pillar WP1 or WP2. The lower end of the conductor film 30 is located below the semiconductor layer 24 as a lowermost layer and above the insulating layer 22. The upper end of the conductor film 30 is aligned with, for example, the upper end of the insulating layer 25. The conductor film 30 contains, for example, titanium nitride.

The memory structure MS including the insulator films 31, 32, 33, and 35 and the charge storage film 34 is the same as that of the third embodiment.

Each of the plurality of insulator films 73 is provided at the same position as that of each of the plurality of semiconductor layers 24 in the Z direction and functions as the insulator INS. The insulator film 73 extends in the XY plane and is provided between the two insulating layers 23 or the insulating layers 23 and 25. Therefore, the length (film thickness) in the Z direction of the insulator film 73 is substantially equal to the film thickness of the semiconductor layer 24, and there is no portion longer than the film thickness of the semiconductor layer 24. The insulator film 73 contains, for example, silicon oxide.

The structures of the conductive layers 51a and 51b and the conductive layers 52a and 52b are the same as those of the second embodiment.

### 4.2 Producing Method

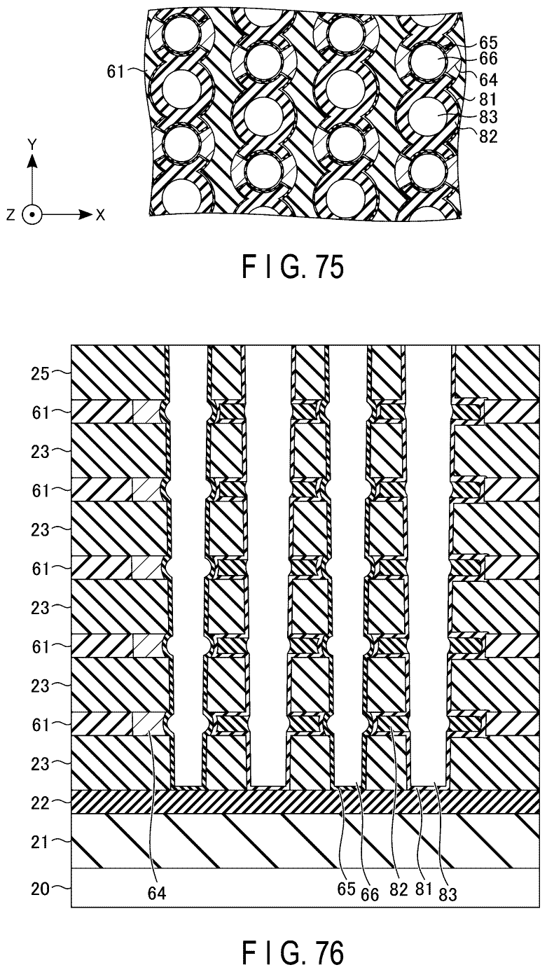

FIGS. 75, 77, 79, 81, 83, 85, and 87 are plan views illustrating an example of the planar layout of the memory device according to the fourth embodiment under production. FIGS. 76, 78, 80, 82, 84, 86, and 88 are cross-sectional views illustrating an example of the cross-sectional structure of the memory device according to the fourth embodiment under production. Each of the cross-sectional views illustrated in FIGS. 76, 78, 80, 82, 84, 86, and 88 corresponds to a cross section cut at the same position as that of line LXXIV-LXXIV illustrated in FIG. 73 in the planar layout illustrated in FIGS. 75, 77, 79, 81, 83, 85, and 87.

First, the same structure as that in FIGS. 57 and 58 in the third embodiment is formed by the same step as that in the third embodiment.

Next, as illustrated in FIGS. 75 and 76, a plurality of holes H8 are embedded by an insulator film 81, a sacrificial member 82, and a sacrificial member 83. Specifically, the thin insulator film 81 is formed in the plurality of holes H8. Each of a plurality of grooves formed in each of the plurality of holes H8 is not closed by the insulator film 81. Thereafter, each of the plurality of grooves formed in each of the plurality of holes H8 is embedded by the sacrificial member 82. The plurality of holes H8 are embedded by the sacrificial member 83. The insulator film 81 contains, for example, silicon oxide. The sacrificial member 82 contains, for example, silicon nitride. The sacrificial member 83 contains, for example, polysilicon.

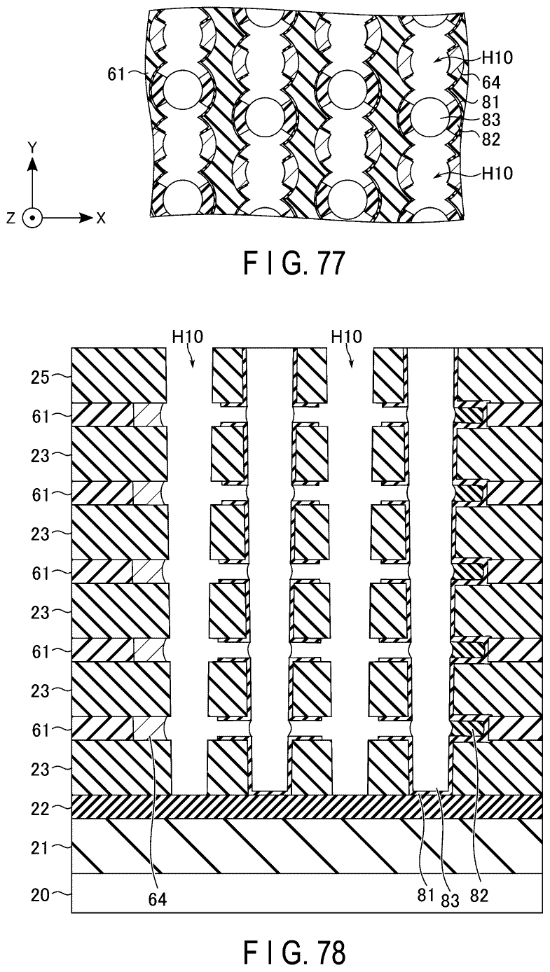

Next, as illustrated in FIGS. 77 and 78, a sacrificial member 66 and an insulator film 65 provided in the region corresponding to the conductive pillar WP1 are removed to form a plurality of holes H10. In a case where the insulator film 65 is removed, the insulator film 81 exposed to the inside of the holes H10 is also removed. As a result, the plurality of sacrificial members 64 and 82 stacked apart from each other are exposed inside the holes H10. Thereafter, the plurality of sacrificial members 82 are removed from the plurality of holes H10. As a result, a plurality of grooves are formed in the holes H10, and the sacrificial member 83 is exposed in the grooves.

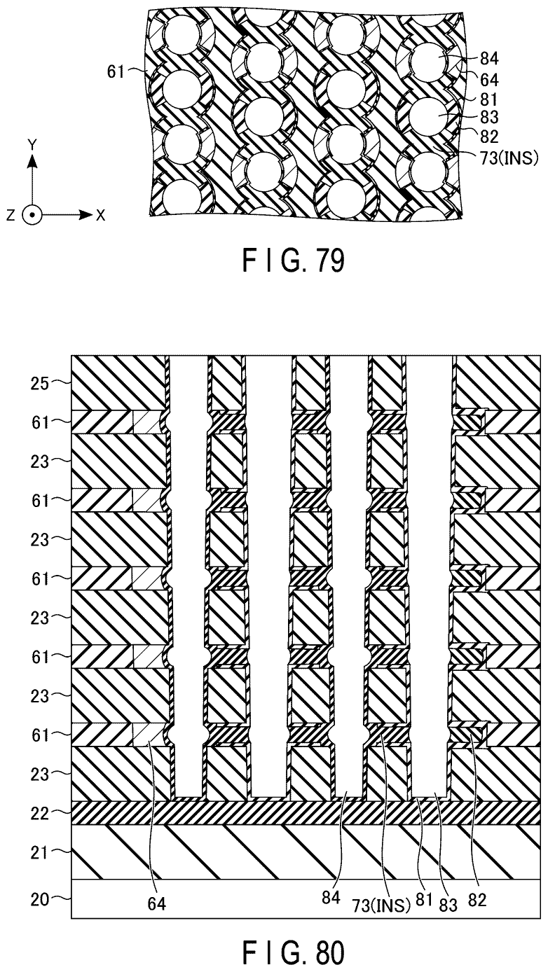

Next, as illustrated in FIGS. 79 and 80, the plurality of holes H10 are embedded by an insulator film 73 and a sacrificial member 84. Specifically, the groove formed by removing the sacrificial member 82 is embedded by the insulator film 73. Thereafter, the plurality of holes H10 are embedded by the sacrificial member 84. The sacrificial member 84 contains, for example, polysilicon.

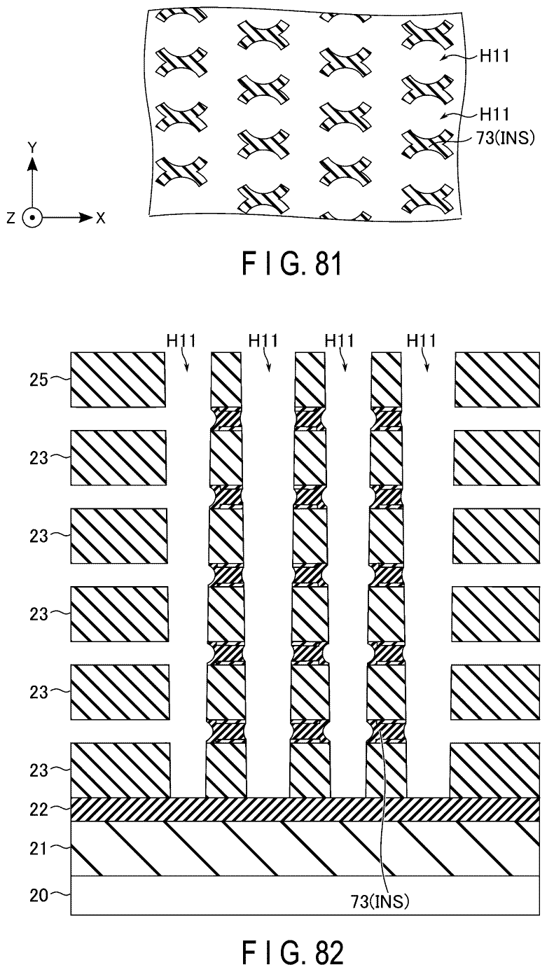

Next, as illustrated in FIGS. 81 and 82, parts of the sacrificial member 84 and the insulator film 73 provided in the region corresponding to the conductive pillar WP1, and parts of the sacrificial member 83 and the insulator film 81 provided in the region corresponding to the conductive pillar WP2 are removed to form a plurality of holes H11. The plurality of sacrificial members 64 and 82 stacked apart from each other are exposed inside the hole H11 corresponding to the conductive pillar WP1.

Subsequently, the plurality of sacrificial members 82 are removed from the hole H11 corresponding to the conductive pillar WP2. As a result, a plurality of grooves are formed in each of the plurality of holes H11 corresponding to the conductive pillar WP2. Since the insulator film 81 is formed on the sacrificial member 61 inside the plurality of grooves in each of the plurality of holes H11 corresponding to the conductive pillar WP2, the sacrificial member 61 is not exposed.

Subsequently, the plurality of sacrificial members 64 are removed from the hole H11 corresponding to the conductive pillar WP1. As a result, the plurality of grooves are formed in each of the plurality of holes H11 corresponding to the conductive pillar WP1, and the sacrificial member 61 is exposed inside the grooves. Thereafter the plurality of sacrificial members 61 are removed from the hole H11 corresponding to the conductive pillar WP1. Furthermore, the insulator film 81 is removed from the hole H11 corresponding to the conductive pillar WP2. As a result, the plurality of holes H11 are connected in one via the plurality of grooves.

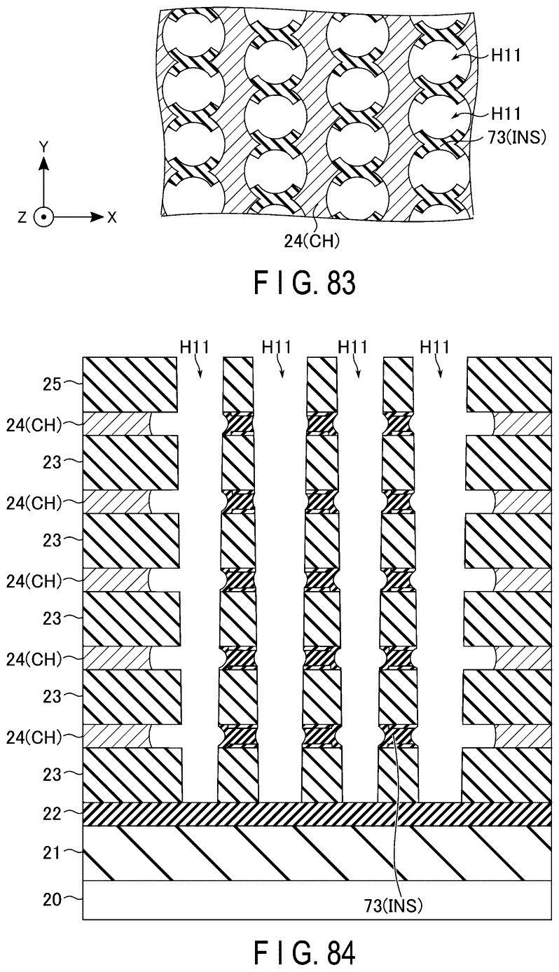

Next, as illustrated in FIGS. 83 and 84, the semiconductor layer 24 is formed via the plurality of holes H11 connected in one via the plurality of grooves. As a result, a region where the channel structure CH is to be formed in the plurality of grooves formed in each of the plurality of holes H11 is embedded by the semiconductor layer 24. The plurality of holes H11 are divided again by the semiconductor layer 24.

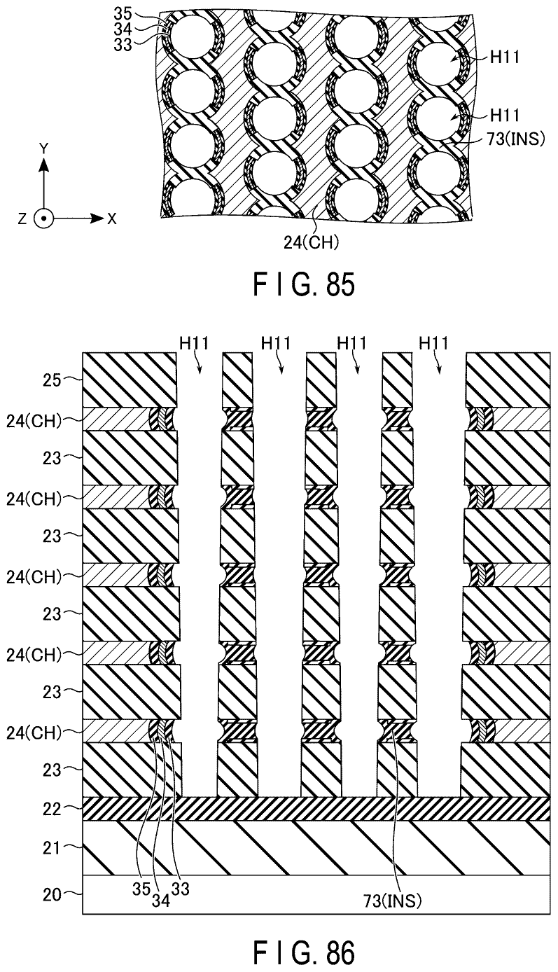

Next, as illustrated in FIGS. 85 and 86, the insulator film 35, the charge storage film 34, and the insulator film 33 are formed via the plurality of holes H11. As a result, each of the plurality of grooves formed in each of the plurality of holes H11 is embedded by the stacked film of the insulator film 35, the charge storage film 34, and the insulator film 33.

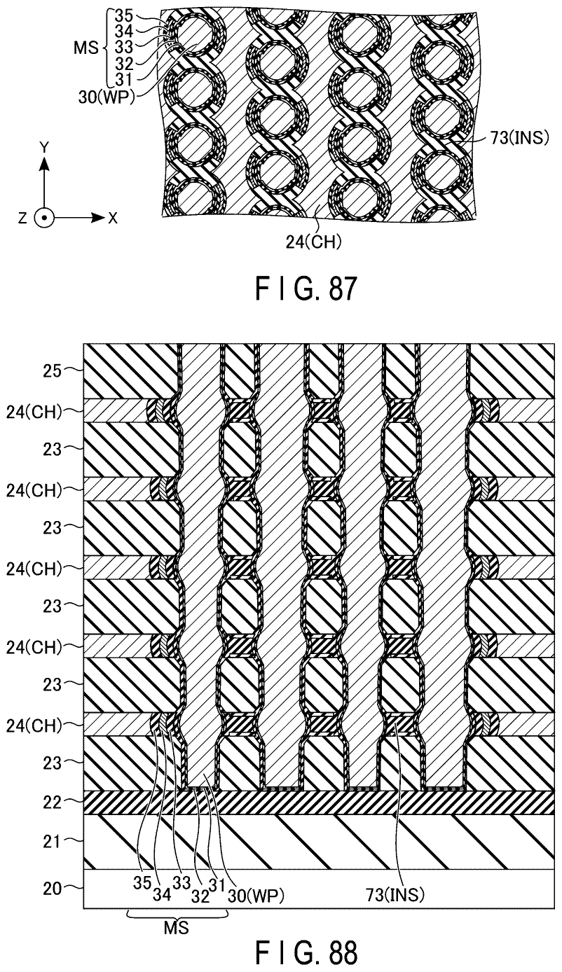

Next, as illustrated in FIGS. 87 and 88, the insulator film 32, the insulator film 31, and the conductor film 30 are formed via the plurality of holes H11 to embed the plurality of holes H11.

Thereafter, a structure above the stacked structure of the memory cell array 10 is formed. Thus, a memory device 3 is formed.

### 4.3 Effects According to Fourth Embodiment

According to the fourth embodiment, the region where the plurality of holes corresponding to the conductive pillars WP1 and WP2 are formed has a stacked structure of the insulating layer 23 and the sacrificial member 61. As a result, for example, in the region where the plurality of holes corresponding to the conductive pillars WP1 and WP2 are formed, the processing becomes easier than in a case where the region where the stacked structure of the silicon oxide layer and the silicon nitride layer is processed and the region where the stacked structure including only the silicon oxide layer is processed are mixed. Therefore, an increase in the producing cost of the memory device 3 can be suppressed.

The plurality of holes corresponding to the conductive pillars WP1 and WP2 are collectively formed. As a result, the step of processing the stacked structure of the insulating layer 23 and the sacrificial member 61 in the Z direction can be performed once. Therefore, an increase in the producing cost of the memory device 3 can be suppressed.

In a case where a plurality of holes corresponding to the conductive pillars WP1 and WP2 are formed, all the holes correspond to any of the conductive pillars WP1 and WP2. As a result, the integration density of the memory cell transistors MT can be increased as compared with the case where a part of the collectively formed holes is used as the conductive pillars WP1 and WP2.

### 5. OTHER MODIFICATIONS

Note that various modifications can be applied to the first embodiment, the second embodiment, the third embodiment, and the fourth embodiment described above.

In the first embodiment described above, the case where the conductive pillars WP and TP are disposed in square as viewed in the Z direction has been described, but the present invention is not limited thereto. For example, the conductive pillars WP and TP may be disposed in a staggered form as viewed in the Z direction.

In the modification of the first embodiment described above, the case where the conductive pillar WP and the insulating pillar RP are disposed in square as viewed in the Z direction has been described, but the present invention is not limited thereto. For example, the conductive pillars WP and the insulating pillar RP may be disposed in a staggered form as viewed in the Z direction.

In the second, third, and fourth embodiments described above, the case where the conductive pillars WP1 and WP2 are disposed in a staggered form as viewed in the Z direction has been described, but the present invention is not limited thereto. For example, the conductive pillars WP1 and WP2 may be disposed in square as viewed in the Z direction.

While certain embodiments have been described, these embodiments have been presented by way of example only, and are not intended to limit the scope of the inventions. Indeed, the novel methods and devices described herein may be embodied in a variety of other forms; furthermore, various omissions, substitutions and changes in the form of the methods and devices described herein may be made without departing from the spirit of the inventions. The accompanying claims and their equivalents are intended to cover such forms or modifications as would fall within the scope and spirit of the inventions.

What is claimed is:

1. A memory device comprising:
a first conductive pillar and a second conductive pillar, each of the first conductive pillar and the second conductive pillar extending in a first direction and arranged in a second direction intersecting the first direction;
a first semiconductor layer and a second semiconductor layer, each of the first semiconductor layer and the second semiconductor layer extending in the second direction at a first position in the first direction and sandwiching the first conductive pillar and the second conductive pillar in a third direction intersecting the first direction and the second direction;
a first insulator film provided between the first semiconductor layer and the second semiconductor layer and between the first conductive pillar and the second conductive pillar at the first position and having a first portion along a circle centered on the first conductive pillar on a surface facing the first semiconductor layer and the second semiconductor layer;
a first charge storage film provided between the first conductive pillar and the first semiconductor layer at the first position; and
a second charge storage film provided between the first conductive pillar and the second semiconductor layer at the first position and separated from the first charge storage film.

2. The memory device according to claim 1, wherein
the first insulator film further includes a second portion along a circle centered on the second conductive pillar on the surface facing the first semiconductor layer and the second semiconductor layer.

3. The memory device according to claim 2, wherein
the first portion and the second portion of the first insulator film form a convex shape.

4. The memory device according to claim 2, wherein
the first portion and the second portion of the first insulator film has a concave shape.

5. The memory device according to claim 1, further comprising:
a third charge storage film provided between the second conductive pillar and the first semiconductor layer at the first position; and
a fourth charge storage film provided between the second conductive pillar and the second semiconductor layer at the first position and separated from the third charge storage film, wherein
the first charge storage film and the second charge storage film have different shapes from those of the third charge storage film and the fourth charge storage film.

6. The memory device according to claim 5, wherein
the first charge storage film and the second charge storage film are shorter than the third charge storage film and the fourth charge storage film.

7. The memory device according to claim 1, wherein
the first insulator film surrounds the first conductive pillar.

8. The memory device according to claim 1,
wherein the first insulator film further includes a third portion along a circle centered on a position different from those of the first conductive pillar and the second conductive pillar on the surface facing the first semiconductor layer and the second semiconductor layer.

9. The memory device according to claim 1, further comprising:
a third semiconductor layer and a fourth semiconductor layer, each of the third semiconductor layer and the fourth semiconductor layer extending in the second direction at a second position different from the first position in the first direction and sandwiching the first conductive pillar and the second conductive pillar in the third direction;
a second insulator film provided between the third semiconductor layer and the fourth semiconductor layer and between the first conductive pillar and the second conductive pillar at the second position and having a fourth portion along a circle centered on the first conductive pillar on a surface facing the third semiconductor layer and the fourth semiconductor layer;
a fifth charge storage film provided between the first conductive pillar and the third semiconductor layer at the second position; and
a sixth charge storage film provided between the first conductive pillar and the fourth semiconductor layer at the second position and separated from the fifth charge storage film.

10. The memory device according to claim 9, wherein
the first insulator film and the second insulator film are separated from each other.

11. The memory device according to claim 9, wherein
the first insulator film and the second insulator film are formed as a continuous film.

12. The memory device according to claim 9, further comprising
an insulating layer provided between the first insulator film and the second insulator film.

13. The memory device according to claim 1, further comprising
a third conductive pillar and a fourth conductive pillar, each of the third conductive pillar and fourth conductive pillar extending in the first direction, arranged in the second direction, and provided on a side opposite to the first conductive pillar and the second conductive pillar with respect to the first semiconductor layer, wherein
the first conductive pillar, the second conductive pillar, the third conductive pillar, and the fourth conductive pillar are disposed in square as viewed in the first direction.

14. The memory device according to claim 1, further comprising
a third conductive pillar and a fourth conductive pillar, each of the third conductive pillar and fourth conductive pillar extending in the first direction, arranged in the second direction, and provided on a side opposite to the first conductive pillar and the second conductive pillar with respect to the first semiconductor layer, wherein
the first conductive pillar, the second conductive pillar, the third conductive pillar, and the fourth conductive pillar are disposed in a staggered form as viewed in the first direction.

15. The memory device according to claim 1, further comprising a substrate, wherein
the first direction is a direction substantially perpendicular to the substrate, and
the second direction and the third direction are directions substantially horizontal to the substrate.
